(19) United States
(12) Patent Application Publication
(10) Pub. No.: US 2024/0387561 A1
(43) Pub. Date: Nov. 21, 2024

(54) DISPLAY APPARATUS

(71) Applicant: BEIJING SHIYAN TECHNOLOGY CO., LTD, Beijing (CN)

(72) Inventors: Jian GAO, Beijing (CN); Sen Ma, Beijing (CN); Xue Dong, Beijing (CN); Tao Hong, Beijing (CN); Kuanjun Peng, Beijing (CN); Zhongyuan Wu, Beijing (CN)

(21) Appl. No.: 18/771,716

(22) Filed: Jul. 12, 2024

Related U.S. Application Data
(63) Continuation-in-part of application No. 18/026,754, filed on Mar. 16, 2023.

(51) Int. Cl. H01L 27/12; G02B 30/27

(52) U.S. Cl. CPC H01L 27/124; G02B 30/27

(57) ABSTRACT

Provides is a display apparatus including: a display panel including: pixel islands in arrays in a row direction and a column direction, pixel islands include n sub-pixels at intervals in the row direction, n>1. The display panel has a preset horizontal direction and a preset vertical direction perpendicular to the preset horizontal direction; a light-splitting assembly at a display side of the display panel, the light-splitting assembly includes light-splitting repeating units extending in a first direction and continuously in the preset horizontal direction, light-splitting repeating units include M light-splitting structures extending in the first direction; a width of M light-splitting structures is equal to a width of K pixel islands in row direction, M and K are positive integers, an included angle between the first direction and the preset horizontal direction and an included angle between the first direction and the preset vertical direction are greater than 0.

### CROSS-REFERENCE TO RELATED APPLICATIONS

This application is a continuation-in-part of U.S. application Ser. No. 18/026,754, filed on Mar. 16, 2023, which is a National Stage of International Application No. PCT/CN2022/094207, filed May 20, 2022, which is hereby incorporated by reference in its entirety.

### FIELD

The present disclosure relates to the technical field of display, and particularly relates to a display apparatus.

### BACKGROUND

With the continuous development of a display technology, a three dimensional (3D) display technology has received increasing attention. A vivid stereoscopic display picture can be exhibited with the aid of the 3D display technology. Its principle is to receive a left eye image and a right eye image with some parallax through the left eye and the right eye respectively, and then superimpose and fuse image information through the brain, so as to create a 3D visual display effect. Since it's common practice to use both landscape and portrait orientations on mobile terminal products, an urgent demand for a bidirectional naked-eye 3D product with perfect compatibility between landscape and portrait orientations rises.

### SUMMARY

An embodiment of the present disclosure provides a display apparatus, including: a display panel, where the display panel includes: a plurality of sub-pixels arranged in arrays in a row direction and a column direction, the plurality of sub-pixels are divided into a plurality of pixel islands; each of the pixel islands includes n sub-pixels arranged at intervals in the row direction, where n is an integer greater than 1; and the display panel has a preset horizontal direction and a preset vertical direction perpendicular to the preset horizontal direction; and a light-splitting assembly at a display side of the display panel, where the light-splitting assembly includes a plurality of light-splitting repeating units extending in a first direction and continuously arranged in the preset horizontal direction; each light-splitting repeating unit includes M light-splitting structures extending in the first direction; in the row direction, a width of the M light-splitting structures is equal to a width of K pixel islands, where M and K are positive integers; and both an included angle between the first direction and the preset horizontal direction and an included angle between the first direction and the preset vertical direction are greater than 0.

In some embodiments, the plurality of sub-pixels are divided into a plurality of pixel groups, the plurality of pixel groups are arranged in arrays in the row direction and the column direction, each of the pixel groups includes: a first sub-pixel, a second sub-pixel, a third sub-pixel, and a fourth sub-pixel arrayed sequentially in the column direction;
the display panel further includes: an array substrate;
the array substrate includes:
a plurality of data lines, arranged at intervals in the row direction, and each of the data lines extending in the column direction;
a plurality of scanning lines, arranged at intervals in the column direction, and each of the scanning lines extending in the row direction;
where the plurality of scanning lines comprise a first scanning line and a second scanning line adjacent to each other in the column direction, the first scanning line is configured to apply a first scanning signal to the first sub-pixel and the third sub-pixel, the second scanning line is configured to apply a second scanning signal to the second sub-pixel and the fourth sub-pixel; and
the plurality of data lines comprise a first data line and a second data line, the first data line is configured to apply a first data signal to the third sub-pixel and the fourth sub-pixel, the second data line is configured to apply a second data signal to the first sub-pixel and the second sub-pixel.

In some embodiments, each of the sub-pixels includes a pixel electrode, the first sub-pixel includes a first pixel electrode, the second sub-pixel includes a second pixel electrode, the third sub-pixel includes a third pixel electrode, the fourth sub-pixel includes a fourth pixel electrode; and the first pixel electrode, the second pixel electrode, the third pixel electrode, and the fourth pixel electrodes are sequentially arranged in the column direction;
angles between main body extension directions of the first pixel electrode, the second pixel electrode, the third pixel electrode, and the fourth pixel electrode and the row direction are greater than 0; and
angles between the main body extension directions of the first pixel electrode, the second pixel electrode, the third pixel electrode, and the fourth pixel electrode and the column direction are greater than 0.

In some embodiments, the first pixel electrode, the second pixel electrode, the third pixel electrode, and the fourth pixel electrode have a same main body extension direction; and the main body extension direction is the same as the first direction.

In some embodiments, each of the pixel electrodes includes a first end and a second end arranged opposite with each other;
at least a portion of a second end of the first pixel electrode is arranged on a side of the first scanning line proximate to the second scanning line; at least a portion of a first end of the third pixel electrode is arranged on a side of the first scanning line far away from the second scanning line; at least a portion of a second end of the second pixel electrode is arranged on a side of the second scanning line far away from the first scanning line; and at least a portion of a first end of the fourth pixel electrode is arranged on a side of the second scanning line proximate to the first scanning line;
in a same pixel group, the first pixel electrode and the third pixel electrode are overlapped with the first scanning line, the second pixel electrode and the fourth pixel electrode are overlapped with the second scanning line, at least a portion of a first end of the second pixel electrode is arranged on the side of the first scanning line far away from the second scanning line, and at least a portion of a second end of the fourth pixel electrode is arranged on the side of the second scanning line far away from the first scanning line.

In some embodiments, each of the sub-pixels includes an active structure, and the active structure includes a first connecting end and a second connecting end arranged opposite with each other; where the first sub-pixel includes a first active structure, the second sub-pixel includes a second active structure, the third sub-pixel includes a third active structure, and the fourth sub-pixel includes a fourth active structure;
a first connecting end of the first active structure is connected with the second data line, a second connecting end of the first active structure is connected with the second end of the first pixel electrode;
a first connecting end the second active structure is connected with the second data line, a second connecting end of the second active structure is connected with the second end of the second pixel electrode;
a first connecting end of the third active structure is connected with the first end of the third pixel electrode, a second connecting end of the third active structure is connected with the first data line;
a first connecting end of the fourth active structure is connected with the first end of the fourth pixel electrode, a second connecting end of the fourth active structure is connected with the first data line.

In some embodiments, in a same pixel group, the first active structure and the third active structure are arranged facing with each other in the row direction, the second active structure and the fourth active structure are arranged facing with each other in the row direction, both the second active structure and the fourth active structure are arranged on a same side of the first active structure in the column direction;
in the column direction, the first connecting end and the second connecting end of the first active structure of the first sub-pixel are arranged different sides of the first scanning line respectively; the first connecting end and the second connecting end of the second active structure of the second sub-pixel are arranged different sides of the second scanning line respectively; the first connecting end and the second connecting end of the third active structure of the third sub-pixel are arranged different sides of the first scanning line respectively; a first connecting end and the second connecting end of the fourth active structure of the fourth sub-pixel are arranged different sides of the second scanning line respectively.

In some embodiments, the plurality of data lines comprise a plurality of first data lines and a plurality of second data lines, the plurality of first data lines and the plurality of second data lines are alternately arranged in the row direction;
the plurality of scanning lines comprise a plurality of first scanning lines and a plurality of second scanning lines, the plurality of first scanning lines and the plurality of second scanning lines are alternately arranged in the column direction;
the second connecting end of the first active structure and the second connecting end of the second active structure are arranged between the second data line connected and the first data line adjacent to the second data line connected; and the first connecting end of the third active structure and the first connecting end of the fourth active structure are arranged between the first data line connected and the second data line adjacent to the first data line connected.

In some embodiments, in the same pixel group, neither the first active structure nor the second active structure extends beyond an edge, proximate to the first data line, of the second data line connected; and neither the third active structure nor the fourth active structure extends beyond an edge, proximate to the second data line, of the first data line connected.

In some embodiments, the plurality of pixel groups comprise a first pixel group and a second pixel group adjacent to each other in the row direction;
in the row direction, a first active structure in the first pixel group and a third active structure in the second pixel group are arranged at intervals and in the same row, and a second active structure in the first pixel group and a fourth active structure in the second pixel group are arranged at intervals and in the same row;
in the column direction, the first active structure in the first pixel group and the second active structure in the first pixel group are arranged at intervals and in the same column, and the third active structure in the second pixel group and the fourth active structure in the second pixel group are arranged at intervals and in the same column.

In some embodiments, in the column direction, a first end of a third pixel electrode in the second pixel group, a second end of a first pixel electrode in the first pixel group, a first end of a fourth pixel electrode in the second pixel group, and a second end of a second pixel electrode in the first pixel group are arranged at intervals in sequence.

In some embodiments, the first pixel electrode includes a first main body portion and a first connecting portion, the first main body portion is connected with the first connecting portion, one end of the first connecting portion far away from the first main body portion serves as the second end of the first pixel electrode, the first connecting portion of the first pixel electrode extends towards a direction far away from the second pixel electrode adjacent to the first pixel electrode;
the fourth pixel electrode includes a second main body portion and a second connecting portion, the second main body portion is connected with the second connecting portion, one end of the second connecting portion far away from the second main body portion serves as the first end of the fourth pixel electrode, the second connecting portion of the fourth pixel electrode extends towards a direction far away from the third pixel electrode adjacent to the first pixel electrode.

In some embodiments, an angle between an extension direction of the first connecting portion and an extension direction of the first main body portion is substantially same as an angle between an extension direction of the second connecting portion and an extension direction of the second main body portion.

In some embodiments, the scanning line includes a connection zone, the connection zone includes a first structural portion, a second structural portion, and a third structural portion; where the first structural portion and the third structural portion both extend in the row direction, the first structural portion and the third structural portion are arranged at intervals in the column direction; the second structural portion extends in the column direction, one end of the second structural portion is connected with the first structural portion, and the other end of the second structural portion is connected with the third structural portion;
the first active structure includes a first bending portion, the second active structure includes a second bending portion, the third active structure includes a third bending portion, the fourth active structure includes a fourth bending portion; where the first bending portion and the third bending portion are arranged between the first structural portion and the third structural portion of the first scanning line adjacent to the first bending portion and the third bending portion; the second bending portion and the fourth bending portion are arranged between the first structural portion and the third structural portion of the second scanning line adjacent to the second bending portion and the fourth bending portion;
a first bending portion of the first pixel group and a third bending portion of the second pixel group are arranged on different sides of the second structural portion of the first scanning line in the row direction; the first bending portion of the first pixel group and the third bending portion of the second pixel group are concaved in a direction far away from the second structural portion of the first scanning line, respectively; and a second bending portion of the first pixel group and a fourth bending portion of the second pixel group are arranged on different sides of the second structural portion of the second scanning line in the row direction; and the second bending portion of the first pixel group and the fourth bending portion of the second pixel group are concaved in a direction far away from the second structural portion of the second scanning line, respectively.

In some embodiments, a portion of the first bending portion and a portion of the second bending portion are overlapped with the second data line, and a portion of the third bending portion and a portion of the fourth bending portion are overlapped with the first data line.

In some embodiments, in the column direction, a first end of a third pixel electrode in the second pixel group, a first end of a fourth pixel electrode in the second pixel group, a second end of a first pixel electrode in the first pixel group, and a second end of a second pixel electrode in the first pixel group are arranged at intervals in sequence.

In some embodiments, the scanning line includes a connection zone, the connection zone includes a first structural portion, a second structural portion, and a third structural portion; where the first structural portion and the third structural portion both extend in the row direction, the first structural portion and the third structural portion are arranged at intervals in the column direction; the second structural portion extends in the column direction, one end of the second structural portion is connected with the first structural portion, and the other end of the second structural portion is connected with the third structural portion;
the first active structure includes a first extension, the second active structure includes a second extension, the third active structure includes a third extension, the fourth active structure includes a fourth extension; where, in the column direction, the first extension and the third extension are arranged between the first structural portion and the third structural portion of the first scanning line adjacent to the first extension and the third extension, and the second extension and the fourth extension are arranged between the first structural portion and the third structural portion of the second scanning line adjacent to the second extension and the fourth extension;
a first extension of the first pixel group and a third extension of the second pixel group are arranged different sides of the second structural portion of the first scanning line in the row direction, and the first extension of the first pixel group and the third extension of the second pixel group extend in the column direction; and a second extension of the first pixel group and a fourth extension of the second pixel group are arranged different sides of the second structural portion of the second scanning line in the row direction, and the second extension of the first pixel group and the fourth extension of the second pixel group extend in the column direction.

In some embodiments, in the same pixel group, the first pixel electrode is in a mirror image symmetric structure with the fourth pixel electrode, and the second pixel electrode is in a mirror image symmetric structure with the third pixel electrode.

In some embodiments, the display panel further includes: an opposite substrate arranged opposite the array substrate and including a light-shielding layer, where the light-shielding layer includes a plurality of sub-pixel aperture zones, the plurality of sub-pixel aperture zones being arranged in one-to-one correspondence with the plurality of sub-pixels.

In some embodiments, the display apparatus further comprises: a spacer dielectric layer between the light-splitting assembly and the display panel.

### BRIEF DESCRIPTION OF THE DRAWINGS

To describe technical solutions in embodiments of the present disclosure more clearly, the accompanying drawings required for describing the embodiments are briefly introduced below. Obviously, the accompanying drawings in the following description show merely some embodiments of the present disclosure, and those of ordinary skill in the art would also be able to derive other accompanying drawings from these accompanying drawings without creative efforts.

FIG. 1 is a schematic structural diagram of a display apparatus according to an embodiment of the present disclosure.

FIG. 2 is a schematic of a view formed in a space after light emitted from a sub-pixel is split by a light-splitting structure directly above the sub-pixel according to an embodiment of the present disclosure.

FIG. 3 is a schematic diagram of a view received by human eyes when a connection line between the human eyes is parallel to the preset horizontal direction.

FIG. 4 is a schematic diagram of a view received by human eyes when a connection line between the human eyes is parallel to the preset vertical direction.

FIG. 5 is a schematic structural diagram of another display apparatus according to an embodiment of the present disclosure.

FIG. 6 is an angular spectrogram of light emission of sub-pixels of a display apparatus according to an embodiment of the present disclosure.

FIG. 7 is a distribution diagram of an angular spectrum of a sub-pixel in a horizontal direction according to an embodiment of the present disclosure.

FIG. 8 is a schematic structural diagram of another display apparatus according to an embodiment of the present disclosure.

FIG. 9 is a schematic diagram of a view received by human eyes when a connection line between the human eyes is parallel to the preset horizontal direction.

FIG. 10 is a schematic diagram of a view received by human eyes when a connection line between the human eyes is parallel to the preset vertical direction.

FIG. 11 is an angular spectrogram of light emission of sub-pixels of another display apparatus according to an embodiment of the present disclosure.

FIG. 12 is a distribution diagram of an angular spectrum of another sub-pixel in a horizontal direction according to an embodiment of the present disclosure.

FIG. 13 is a schematic structural diagram of yet another display apparatus according to an embodiment of the present disclosure.

FIG. 14 is a schematic diagram of a pixel connection structure of a display panel.

FIG. 15 is a schematic diagram of a pixel connection structure of a display panel provided by at least one embodiment of the present disclosure.

FIG. 16 is a schematic diagram of a partial structure of a display panel provided by at least one embodiment of the present disclosure.

FIG. 17 is a schematic diagram of a partial cross-section corresponding to the display panel of FIG. 16.

FIG. 18 is a schematic diagram of the pixel electrode pattern corresponding to the display panel of FIG. 16.

FIG. 19 is a schematic diagram of the active pattern corresponding to the display panel of FIG. 16.

FIG. 20 is a schematic diagram of a stacking structure of a first conductive pattern, an active pattern, a second conductive pattern, and a third conductive pattern corresponding to the display panel of FIG. 16.

FIG. 21 is a schematic diagram of a second conductive pattern corresponding to the display panel of FIG. 16.

FIG. 22 is a schematic diagram of a partial structure of the stacking structure shown in FIG. 20 after the second through hole is provided on the stacking structure.

FIG. 23 is a schematic diagram of a first conductive pattern corresponding to the display panel of FIG. 16.

FIG. 24 is a schematic diagram of the first through hole pattern corresponding to the display panel of FIG. 16.

FIG. 25 is a schematic diagram of a third conductive pattern corresponding to the display panel of FIG. 16.

FIG. 26 is a schematic diagram of the second through hole pattern corresponding to the display panel of FIG. 16.

FIG. 27 is a schematic diagram of a fourth conductive pattern corresponding to the display panel of FIG. 16.

FIG. 28 is a schematic diagram of a third through hole pattern corresponding to the display panel of FIG. 16.

FIG. 29 is a schematic diagram of an auxiliary conductive pattern corresponding to the display panel of FIG. 16.

FIG. 30 is a schematic diagram of a common electrode pattern corresponding to the display panel of FIG. 16.

FIG. 31 is a schematic diagram of a fourth through hole pattern corresponding to the display panel of FIG. 16.

FIG. 32 is a schematic diagram of a stacking structure of a first conductive pattern and an active pattern corresponding to the display panel of FIG. 16.

FIG. 33 is a schematic diagram of a stacking structure of a first conductive pattern, an active pattern, and a second conductive pattern corresponding to the display panel of FIG. 16.

FIG. 34 is a schematic diagram of a stacking structure of a first conductive pattern, an active pattern, a second conductive pattern, and a first through hole pattern corresponding to the display panel of FIG. 16.

FIG. 35 is a schematic diagram of a stacking structure of a first conductive pattern, an active pattern, a second conductive pattern, a third conductive pattern, a second through hole pattern, a fourth conductive pattern, and a third through hole pattern corresponding to the display panel of FIG. 16.

FIG. 36 is a schematic diagram of a partial structure of another display panel provided by at least one embodiment of the present disclosure.

FIG. 37 is a schematic diagram of a partial cross-section corresponding to the display panel of FIG. 36.

FIG. 38 is a schematic diagram of the first conductive pattern corresponding to the display panel in FIG. 36.

FIG. 39 is a schematic diagram of the active pattern corresponding to the display panel in FIG. 36.

FIG. 40 is a schematic diagram of the second conductive pattern corresponding to the display panel in FIG. 36.

FIG. 41 is a schematic diagram of the first through hole pattern corresponding to the display panel in FIG. 36.

FIG. 42 is a schematic diagram of a third conductive pattern corresponding to the display panel in FIG. 36.

FIG. 43 is a schematic diagram of the second through hole pattern corresponding to the display panel in FIG. 36.

FIG. 44 is a schematic diagram of the fourth conductive pattern corresponding to the display panel in FIG. 36.

FIG. 45 is a schematic diagram of the third through hole pattern corresponding to the display panel of FIG. 36.

FIG. 46 is a schematic diagram of the pixel electrode pattern corresponding to the display panel in FIG. 36.

FIG. 47 is a schematic diagram of the auxiliary electrode pattern corresponding to the display panel in FIG. 36.

FIG. 48 is a schematic diagram of the common electrode pattern corresponding to the display panel in FIG. 36.

FIG. 49 is a schematic diagram of a stacking structure of the first conductive pattern and the active pattern corresponding to the display panel of FIG. 36.

FIG. 50 is a schematic diagram of a stacking structure of the first conductive pattern, the active pattern, and the second conductive pattern corresponding to the display panel of FIG. 36.

FIG. 51 is a schematic diagram of a stacking structure of the first conductive pattern, the active pattern, the second conductive pattern, the first through hole pattern, the third conductive pattern, and the second through hole pattern corresponding to the display panel of FIG. 36.

FIG. 52 is a schematic diagram of a stacking structure of the first conductive pattern, the active pattern, the second conductive pattern, the first through hole pattern, the third conductive pattern, the second through hole pattern, the fourth conductive pattern, and the third through hole pattern corresponding to the display panel of FIG. 36.

### DETAILED DESCRIPTION OF THE EMBODIMENTS

For making objectives, technical solutions and advantages of embodiments of the present disclosure clearer, the technical solutions of the embodiments of the present disclosure will be clearly and completely described below in conjunction with the accompanying drawings in the embodiments of the present disclosure. Apparently, the embodiments described are some rather than all of the embodiments of the present disclosure. The embodiments in the present disclosure and features of the embodiments can be combined with each other without conflict. Based on the embodiments of the present disclosure, all other embodiments obtained by those of ordinary skill in the art without making creative efforts fall within the scope of protection of the present disclosure.

Unless otherwise defined, technical or scientific terms used in the present disclosure should have ordinary meanings as understood by those of ordinary skill in the art to which the present disclosure belongs. “First”, “second”, and other similar words used in the present disclosure do not indicate any order, amount or importance, but are only used to distinguish different components. “Include”, “comprise”, and other similar words indicate that elements or objects before the word include elements or objects after the word and their equivalents, without excluding other elements or objects. “Connection”, “connected”, and other similar words are not limited to physical or mechanical connections, but can include electrical connections, which can be direct or indirect.

It should be noted that a size and a shape of each figure in the drawings do not reflect a true scale, but only for illustrating the present disclosure. Throughout the drawings, identical or similar reference numerals denote identical or similar elements or elements having identical or similar functions.

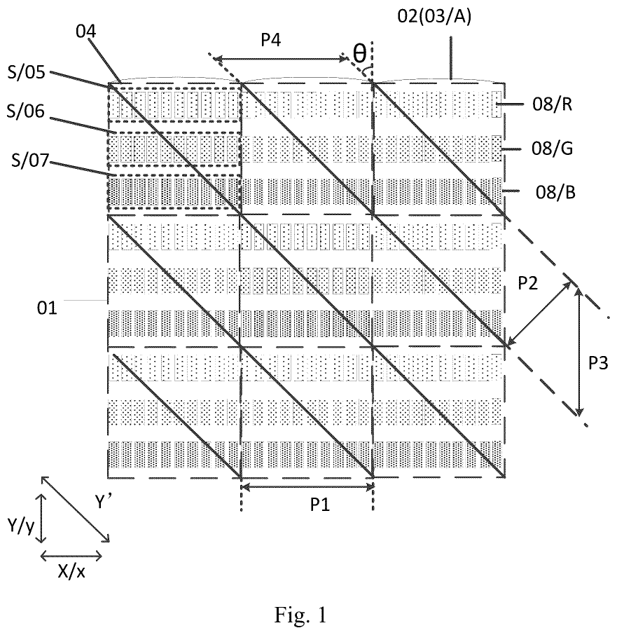

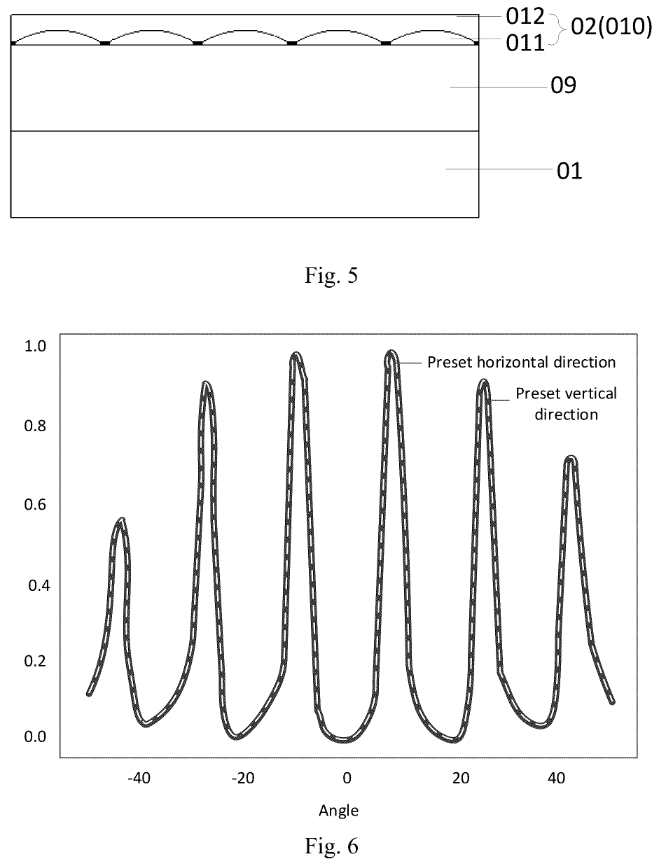

An embodiment of the present disclosure provides a display apparatus. As shown in FIGS. 1 and 5, the display apparatus includes:
a display panel 01, where the display panel 01 includes: a plurality of pixel islands S arranged in arrays in a row direction x and a column direction y; each of the pixel islands S includes n sub-pixels 08 arranged at intervals in the row direction x, where n is an integer greater than 1; the display panel has a preset horizontal direction X and a preset vertical direction Y perpendicular to the preset horizontal direction X; and in FIG. 1, the row direction x is perpendicular to the column direction y; and
a light-splitting assembly 02 at a display side of the display panel 01, where the light-splitting assembly 02 includes a plurality of light-splitting repeating units 03 extending in a first direction Y′ and continuously arranged in the preset horizontal direction X; each light-splitting repeating unit 03 includes M light-splitting structures A extending in the first direction Y′; in the row direction x, a width of the M light-splitting structures A is equal to a width of K pixel islands S, where M and K are positive integers; and both an included angle between the first direction Y′ and the preset horizontal direction X and an included angle between the first direction Y′ and the preset vertical direction Y are greater than 0.

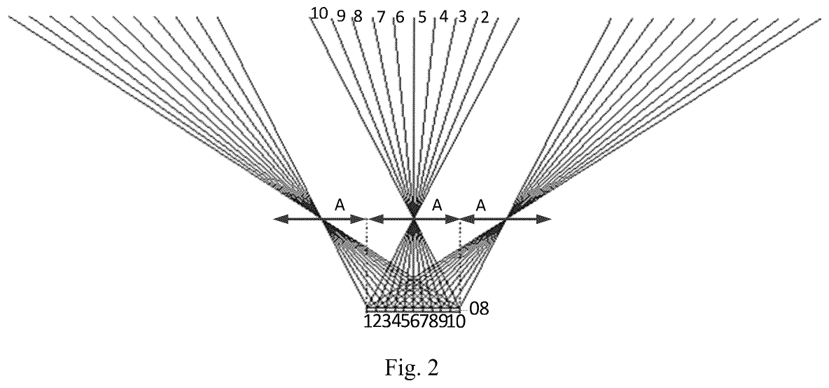

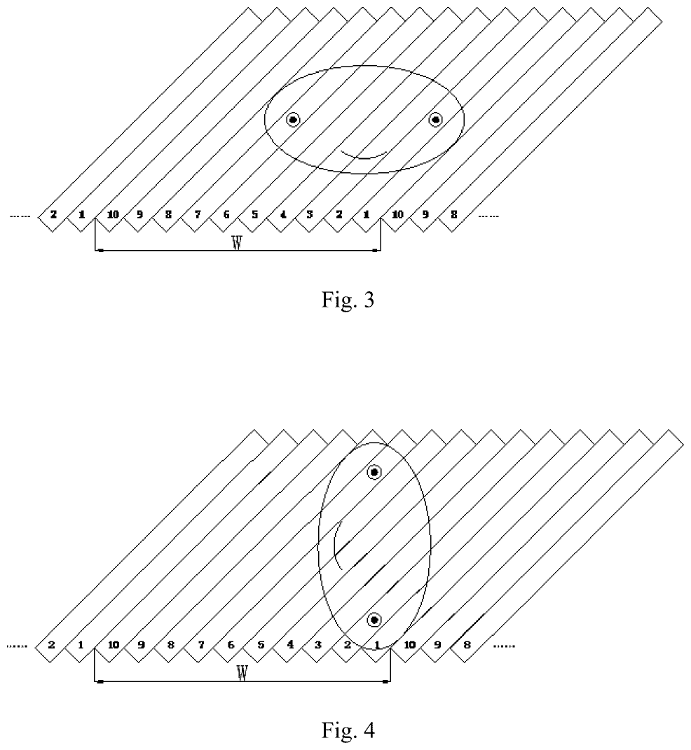

It should be noted that in the row direction x, the width of the M light-splitting structures is equal to the width of K pixel islands, which means that K pixel islands correspond to the M light-splitting structures in the row direction x. For example, in FIG. 1, each pixel island includes 10 sub-pixels, and one light-splitting structure corresponds to 10 sub-pixels. Schematic diagrams of views formed in a space after light emitted from a sub-pixel is split by a light-splitting structure directly above the sub-pixel and a view received by human eyes are shown in FIGS. 2, 3 and 4. A serial number of each zone represents a corresponding viewpoint. FIG. 3 is a schematic diagram of a view received by human eyes when a connection line between the human eyes is parallel to the preset horizontal direction, and FIG. 4 is a schematic diagram of a view received by human eyes when a connection line between the human eyes is parallel to the preset vertical direction. It may be seen from FIGS. 3 and 4 that the human eyes may see a parallax image in both the preset horizontal direction and the preset vertical direction.

According to the display apparatus according to some embodiments of the present disclosure, both an included angle between an extension direction of the light-splitting structures and the preset horizontal direction X and an included angle between the extension direction of the light-splitting structures and the preset vertical direction Y are greater than 0, that is, the light-splitting structures are obliquely placed relative to the preset horizontal direction X and the preset vertical direction Y, such that the human eyes may see the parallax image in both the preset horizontal direction and the preset vertical direction, and further the display apparatus may achieve bidirectional three dimensional (3D) display and improve user experience.

It should be noted that the “space” in the “in a space after light emitted from a sub-pixel is split by a light-splitting structure directly above the sub-pixel” refers to a visible space of the display apparatus.

In some embodiments, light rays emitted from light-emitting zones of all the sub-pixels in K pixel islands and split by M light-splitting structures form a continuous light-emitting zone in a space. The light-splitting structures have small sizes in the row direction, and for K×n sub-pixels corresponding to M light-splitting structures, the human eyes cannot determine which light-splitting structure a light ray is emitted from, so the human eyes see that light rays emitted from K×n sub-pixels and split by the M light-splitting structures above the sub-pixels form a continuous light-emitting zone in a space, and the human eyes cannot see a “black zone” when moving in the visible space. It should be noted that viewing angles include a main lobe viewing angle and a side lobe viewing angle. The main lobe viewing angle refers to a viewing angle formed in a space after light emitted from a sub-pixel is split by a light-splitting structure directly above the sub-pixel. The side lobe viewing angle refers to a viewing angle formed in a space after a light ray emitted from a sub-pixel passes a light-splitting structure near the light-splitting structure directly above the sub-pixel. For example, a primary side lobe viewing angle is formed after light passes a first light-splitting structure adjacent to the light-splitting structure directly above, a secondary side lobe viewing angle is formed after light passes a second light-splitting structure adjacent to the light-splitting structure directly above, and so on.

It should be noted that the preset horizontal direction X and the preset vertical direction Y of the display panel are also a preset horizontal direction X and a preset vertical direction Y of the display apparatus. Specific directions of the preset horizontal direction X and the preset vertical direction Y may be set according to use and appearance of the display apparatus. For example, when the display panel and the display apparatus are in shapes of rectangles and each rectangle has a pair of long sides and a pair of short sides, a direction parallel to the long sides may be the preset horizontal direction while a direction parallel to the short sides may be the preset vertical direction, and alternatively, a direction parallel to the long sides may be the preset vertical direction while a direction parallel to the short sides may be the preset horizontal direction. For example, for a display apparatus like a mobile phone, a direction parallel to short sides may be set as the preset horizontal direction, and for a display apparatus like a tablet computer, a direction parallel to long sides may be set as the preset horizontal direction.

It should be noted that the display apparatus provided in the embodiment of the present disclosure may be used for 3D display, and may further switch between 3D and two dimensional (2D) display. A pixel island may be used as a fractional-pixel of 2D display. One pixel island includes a plurality of sub-pixels, such that 3D display may maintain the same resolution as 2D display. An eye-tracking system is combined, multi-view display with a large viewing angle may be achieved, and 3D display with more pixels per inch (ppi) may be further achieved, with more information and lower color crosstalk between adjacent viewpoints.

In some embodiments, the light-splitting structures are configured to control light-emitting angles of all the sub-pixels, so as to achieve directional light emission.

In some embodiments, the display panel may be one of a liquid crystal display (LCD) panel, an organic light-emitting diode (OLED) display panel, a quantum dot light-emitting diode (QLED), a micro inorganic light-emitting diode (micro LED) display panel, and a mini LED display panel.

In some embodiments, as shown in FIG. 1, every three pixel islands S continuously arranged in the column direction y constitute one pixel repeating unit 04; and
in one pixel repeating unit 04, the sub-pixels 08 of the same pixel island S display the same color, and the sub-pixels 08 of different pixel islands S display different colors.

In some embodiments, as shown in FIG. 1, one pixel repeating unit 04 includes: a first pixel island 05, a second pixel island 06, and a third pixel island 07. The first pixel island 05 includes a plurality of red sub-pixels R, the second pixel island 06 includes a plurality of green sub-pixels G, and the third pixel island 07 includes a plurality of blue sub-pixels B.

In some embodiments, as shown in FIG. 1, all the sub-pixels 08 in one row of pixel islands S display the same color.

In some embodiments, as shown in FIG. 5, the display apparatus further includes:
a spacer dielectric layer 09 between the light-splitting assembly 02 and the display panel 01.

In some embodiments, each light-splitting structure is a cylindrical lens.

In some embodiments, as shown in FIG. 5, the cylindrical lens 010 includes a first resin layer 011 having a protrusion, and a planarized resin layer 012 at one side of the first resin layer 011 facing away from the display panel 01; and the planarized resin layer 012 has a smaller refractive index than the first resin layer 011.

Alternatively, in some embodiments, the cylindrical lens is a liquid crystal lens. When the cylindrical lens is a zoom liquid crystal lens, the cylindrical lens may have different radii of curvature at different viewing angles, such that crosstalk between adjacent viewpoints may be relatively small without obvious change with fluctuation of radii of curvature, and a viewing range of zero crosstalk between left and right eyes may be large.

Certainly, during specific implementation, the light-splitting structure may also be a geometric lens, a diffraction lens, a liquid lens, or another structural apparatus capable of controlling a light-emitting direction of a sub-pixel.

In some embodiments, a placement height of the light-splitting structure, that is, a thickness H of the spacer dielectric layer, satisfies the following condition:

$$H = \frac{n 3 L 1}{W} \times P 2 .$$

L1 is an optimal viewing distance of the display apparatus; W is a width of a projection of a main lobe viewing angle formed by light rays emitted from a sub-pixel at the optimal viewing distance, that is, W is a total width of viewpoints at the optimal viewing distance without repeated viewpoints; n3 is a refractive index of the spacer dielectric layer; and P2 is a width of the cylindrical lens in a direction perpendicular to the first direction.

Optionally,

$$P 2 = \frac{KP 1 cos θ}{M} ;$$

and P1 is a width of a pixel island in the row direction, and θ is an included angle between the first direction and the column direction. That is,

$$H = \frac{n 3 L 1}{W} \times P 2 = \frac{n 3 L 1}{W} \times \frac{KP 1 cos θ}{M} .$$

In some embodiments, a radius of curvature of the cylindrical lens is greater than or equal to 0.9 r and smaller than or equal to 1.24 r, where

$$r = \frac{( n 1 - n 2 )}{n 3} \times \frac{n 3 L 1}{W} \times \frac{KP 1 cos θ}{M} ,$$

n1 is a refractive index of the first resin layer or an extraordinary-light refractive index of the liquid crystal lens, n2 is a refractive index of the planarized resin layer or an ordinary-light refractive index of the liquid crystal lens, n3 is a refractive index of the spacer dielectric layer, L1 is an optimal viewing distance of the display apparatus, and W is a width of a projection of a main lobe viewing angle formed by light rays emitted from the sub-pixel at the optimal viewing distance.

It should be noted that

$$r = \frac{( n 1 - n 2 )}{n 3} \times \frac{n 3 L 1}{W} \times \frac{KP 1 cos θ}{M}$$

is an ideal value of a radius of curvature of the cylindrical lens obtained according to a design of an ideal lens focal plane design, in which a pixel light-emitting surface is located on a focal plane of the lens. During specific implementation, the radius of curvature of the cylindrical lens may be adjusted on the basis of the ideal value of the radius of curvature according to actual needs.

In some embodiments, as shown in FIG. 1, the included angle between the first direction Y′ and the preset horizontal direction X and the included angle between the first direction and the preset vertical direction Y are both 45°. In FIG. 1, the preset vertical direction Y is parallel to the column direction y, that is, θ=45°.

In this way, as shown in FIGS. 3 and 4, the display apparatus provided in the embodiment of the present disclosure may not only enable human eyes to see the parallax image both in the preset horizontal direction and the preset vertical direction, but also achieve the same parallax of left and right eyes both in the preset horizontal direction and the preset vertical direction. Further, the same display effect seen by users in both the preset horizontal direction and the preset vertical direction may be achieved. Moreover, when it is necessary to conduct 3D time-limited layout by comparing boundary data of light-emitting angular spectra of sub-pixels and included angles between a center of eyes of a user and centers of all pixel island groups, the light-emitting angular spectra of the sub-pixels are the same in the preset horizontal direction and the preset vertical direction relative to light-splitting structures, such that layout difficulty may be reduced. For example, in FIGS. 3 and 4, parallax of left and right eyes is 5 in the preset horizontal direction and the preset vertical direction.

In some embodiments, as shown in FIG. 1, the row direction x is parallel to the preset horizontal direction X, and the column direction y is parallel to the preset vertical direction Y.

In some embodiments, when the row direction x is parallel to the preset horizontal direction X, the column direction y is parallel to the preset vertical direction Y, the included angle between the first direction Y′ and the preset horizontal direction X and the included angle between the first direction and the preset vertical direction Y are both 45°, and a width of M light-splitting structures A is equal to a width of K pixel islands S in columns. In some embodiments, a width of a pixel island in the row direction is equal to the width of the pixel island in the column direction. As shown in FIG. 1, both the width of the pixel island in the row direction and the width of the pixel island in the column direction are both P1. Accordingly, a width of a light-splitting structure in the row direction is equal to a width of the light-splitting structure in the column direction.

In some embodiments, M=K=1. That is, in the row direction x, a width P4 of one light-splitting structure is equal to a width P1 of one pixel island, and in the column direction y, a width P3 of one light-splitting structure is equal to a width P1 of one pixel island.

Accordingly, P2=P1 cos 45°, and

$$H = \frac{n 3 L 1}{W} \times P 1 cos 45 ° .$$

It should be noted that in FIG. 1, M=K=1 is taken as an example for description. During specific implementation, M may also be set to be unequal to K. Specifically, M>K=1 may be set, and alternatively, K>M=1 may be set. Alternatively, M and K may be set to be co-prime, and K*n and M may be set to be co-prime.

Then, with the light-splitting structure as a cylindrical lens, K=1, M=1 and n=10 as examples, parameter designs of the light-splitting structure in the display apparatus provided in the embodiment of the present disclosure are introduced. During specific implementation, for example, the display apparatus includes 1080×1920 pixel islands, P1=116.4 μm, and P2=82.307 μm.

It should be noted that since the total number of pixel islands included in the display apparatus is resolution of 2D display, 2D display with retina-level resolution should be achieved for sizes of the pixel islands of the display apparatus provided in the embodiment of the present disclosure, that is, included angles between the pixel islands and human eyes are 1′, such that L1=400 mm. In order to ensure no crosstalk between left and right eyes of 3D display at the optimal viewing distance, it is necessary to maximize the number of viewpoint intervals between the left and right eyes at the optimal viewing distance, such that the sum of widths of viewpoints without repeated viewpoints at the optimal viewing distance and a pupil distance D satisfy

$$D = ( \frac{1}{2} + m ) W ,$$

where m is an integer greater than or equal to 0. According to the condition, it may be seen that with increase in m, a viewpoint density may gradually increase, but a moving range of the human eyes may gradually decrease. In the embodiment of the present disclosure, a large moving range of human eyes is preferable, such that m=0, the pupil distance D of people is usually 65 mm, that is, W=2*D=130 mm. The spacer dielectric layer is generally made of glass, and n3=1.5. L1=400 mm, W=130 mm, n3=1.5 and P1=145.44 μm are substituted into

$$H = \frac{n 3 L 1}{W} \times P 1 cos 45 ° ,$$

and H=537 mm is obtained.

During specific implementation, if n1=1.55, n2=1.42, and n3=1.5, H=537 mm, and

$$r = \frac{( n 1 - n 2 ) H}{n 3} = 46.56 μm .$$

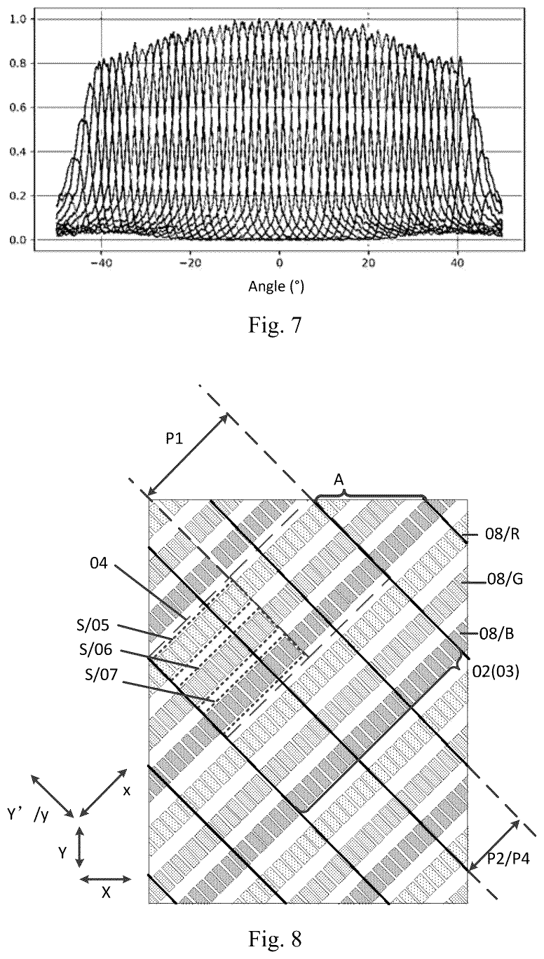

Then, a simulation result of a radius of curvature of the cylindrical lens under the condition that the radius of curvature of the cylindrical lens is greater than or equal to 0.9 r and smaller than or equal to 1.24 r is introduced. According to the above computed parameters: P2=82.307 μm, H=537 mm, and r=46.56 μm, modeling is conducted, and then the radius of curvature is scanned, where the radius of curvature is 58 μm, such that a light-emitting angular spectrum of the sub-pixel numbered 6 under the condition of the radius of curvature of 58 μm as shown in FIG. 6 is obtained. It may be seen from FIG. 6 that angular spectra of the preset horizontal direction and the preset vertical direction are completely coincident, such that a technical effect of 3D compatibility in horizontal and vertical directions may be achieved. FIG. 7 shows distribution of angular spectra of 10 sub-pixels in a horizontal direction, from which crosstalk conditions between all viewpoints may be computed. Primary crosstalk (crosstalk between adjacent viewpoints) is 46.07%-58.62%, secondary crosstalk (crosstalk between spaced viewpoints) is 0.28%-2.78%, and there is no crosstalk after tertiary crosstalk. At the optimal viewing distance (L1=400 mm), crosstalk between left and right eyes is level 5, and crosstalk between the left and right eyes is 0, such that a desirable 3D display effect is achieved. Simulation is conducted according to distribution of crosstalk between left and right eyes corresponding to the above parameters in the whole visible space, and according to a crosstalk standard within 10%, the 3D visible space is 400 mm-600 mm in the preset vertical direction and −7.8°-7.8° in the preset horizontal direction.

Alternatively, in some embodiments, as shown in FIG. 8, both an included angle between the row direction x and the preset horizontal direction X and an included angle between the row direction x and the preset vertical direction Y are greater than 0, and both an included angle between the column direction y and the preset horizontal direction X and an included angle between the column direction y and the preset vertical direction Y are greater than 0; and the first direction Y′ is parallel to the column direction y.

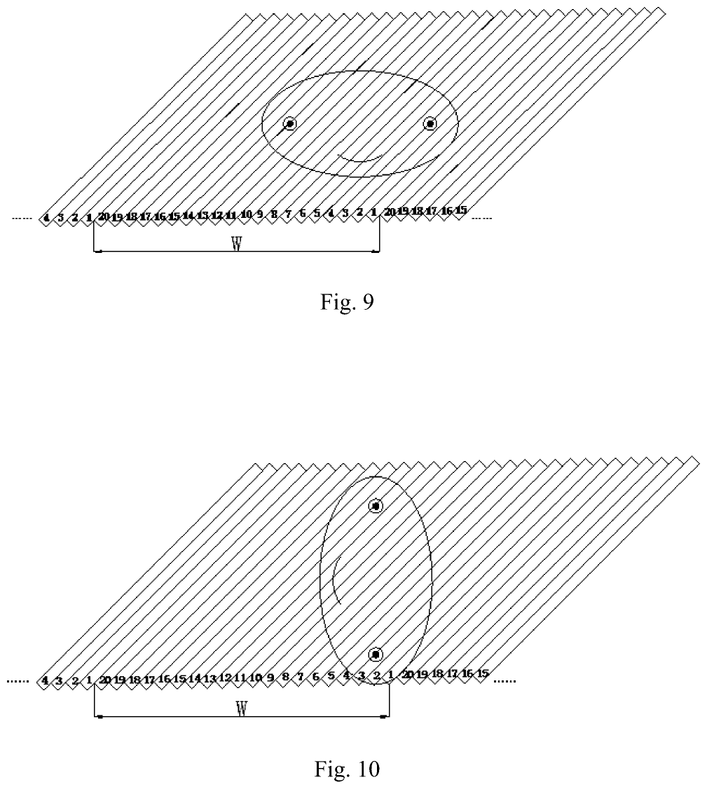

That is, an extension direction of one column of pixel islands and an extension direction of the cylindrical lens are oblique relative to the preset horizontal direction and the preset vertical direction. In the display apparatus shown in FIG. 8, schematic diagrams of views formed in a space after light emitted from a sub-pixel is split by a light-splitting structure directly above the sub-pixel and a view received by human eyes are shown in FIGS. 9 and 10. A serial number of each zone represents a corresponding viewpoint. FIG. 9 is a schematic diagram of a view received by human eyes when a connection line between the human eyes is parallel to the preset horizontal direction, and FIG. 10 is a schematic diagram of a view received by human eyes when a connection line between the human eyes is parallel to the preset vertical direction. That is, when an extension direction of one column of pixel islands and an extension direction of the cylindrical lens are oblique relative to the preset horizontal direction and the preset vertical direction, the human eyes may also see the parallax image in both the preset horizontal direction and the preset vertical direction, such that the display apparatus may achieve bidirectional 3D display.

In some embodiments, M=K=1 may be set. Alternatively, M may be set to be unequal to K. Specifically, M>K=1 may be set, and alternatively, K>M=1 may be set. Alternatively, as shown in FIG. 8, M and K may be set to be integers greater than 1, M and K may be set to be co-prime, and K*n and M may be set to be co-prime.

In some embodiments, as shown in FIGS. 8, K=2, M=3, and n=10. Since the first direction Y′ is parallel to the column direction y, an included angle θ between the first direction Y′ and the column direction y is equal to 0°. Accordingly,

$$P 2 = \frac{2 P 1}{3} , and H = \frac{n 3 L 1}{W} \times P 2 = \frac{n 3 L 1}{W} \times \frac{2 P 1}{3} .$$

Certainly, during specific implementation, K, M and n may also be set as other values.

In the display apparatus provided in some embodiments of the present disclosure, when both M and K are integers greater than 1, that is, pixel islands and light-splitting structures are in many-to-many correspondence, Sizes of the light-splitting structures in the row direction may be prevented from being too small, difficulty of manufacturing the light-splitting assembly may be prevented from being increased, the situation that a light-emitting divergence angle of a sub-pixel is increased due to diffraction of a light-splitting structure too small in size may be further avoided, crosstalk between views increases, and further a display effect is influenced.

When both M and K are integers greater than 1, M and K are co-prime, and K*n and M are co-prime, in some embodiments, the sub-pixels include sub-pixel aperture zones; and in the row direction x, a ratio of a total width of n sub-pixel aperture zones to the width of the pixel island is greater than or equal to 0.9/M and smaller than or equal to 1. That is, an aperture ratio of sub-pixels in the pixel island is greater than or equal to 0.9/M and smaller than or equal to 1.

When both M and K are integers greater than 1, M and K are co-prime, and K*n and M are co-prime, in some embodiments, in the row direction x, a ratio of a width of the sub-pixel aperture zones to the width of the pixel island is 1/M. That is, an aperture ratio of sub-pixels in the pixel island is 1/M. In this way, all the sub-pixels below each light-splitting repeating unit may be arranged in a staggered and complementary manner relative to the corresponding light-splitting structures, such that light-emitting zones of all the sub-pixels in the K pixel islands in the row direction x are complementarily spliced in a space, that is, light paths of all the viewpoints are closely connected, Moire patterns may be eliminated, and a display effect may be improved.

Alternatively, during specific implementation, in the row direction x, a ratio of the width of the sub-pixel aperture zones to the width of the pixel island may be greater than 1/M. Accordingly, in some embodiments, in the row direction x, the light-emitting zones of all the sub-pixels in the K pixel islands overlap each other in a space.

When the ratio of the width of the sub-pixel aperture zones to the width of the pixel island may be greater than 1/M in the row direction x, in some embodiments, in the row direction x, the light-emitting zones of all the sub-pixels in the K pixel islands evenly overlap each other in a space.

In some embodiments, in the row direction x, the ratio of the width of the sub-pixel aperture zones to the width of the pixel island is i/M, where i is an integer greater than 1 and smaller than or equal to M−1. That is, an aperture ratio of sub-pixels in the pixel island is i/M. In this way, all the sub-pixels below each light-splitting repeating unit may be arranged in a staggered, even and overlapped manner relative to the corresponding light-splitting structures, such that light-emitting zones of all the sub-pixels in the K pixel islands evenly overlap each other, that is, light paths of all the viewpoints evenly overlap each other, and similarly, Moire patterns may be eliminated, and a display effect may be improved.

It should be noted that when an aperture ratio of the sub-pixels in the pixel island is i/M and i is an integer greater than 1 and smaller than or equal to M−1, compared with the condition that the pixel island corresponds to the light-splitting structures, the aperture ratio of the sub-pixels may be further improved under the same number of light-splitting structures.

It should be noted that for example, in FIG. 8, a ratio of a width of opening zones of sub-pixels 08 to a width of a pixel island S in the row direction x is ⅔, that is, in the row direction, a ratio of a total width of n sub-pixel aperture zones to the width of the pixel island is (M−1)/M. That is, in FIG. 8, an aperture ratio of sub-pixels in the pixel island is ⅔. When an aperture ratio of the sub-pixels in the pixel island is (M−1)/M, the aperture ratio of the sub-pixels may be improved to the maximum extent under the condition that the light-emitting zones of all the sub-pixels in K pixel islands evenly overlap each other in a space in the row direction.

In some embodiments, when the light-emitting zones of all the sub-pixels in K pixel islands evenly overlap each other in a space, a ratio of an area of an overlapping zone of light-emitting zones of two sub-pixels having adjacent serial numbers to an area of a light-emitting zone of one of the sub-pixels is (i−1)/i. A ratio of an area of an overlapping zone of light-emitting zones of two sub-pixels having adjacent serial numbers to an area of one of the sub-pixels is (i−1)/M.

It should be noted that when a ratio of a total width of n sub-pixel aperture zones to the width of the pixel island is 1/M in the row direction, that is, i=1, light-emitting zones of all the sub-pixels do not overlap each other in a space. When i=2, a ratio of an area of an overlapping zone of light-emitting zones of two sub-pixels having adjacent serial numbers to an area of a light-emitting zone of one of the sub-pixels is ½, and a ratio of an area of an overlapping zone of light-emitting zones of two sub-pixels having adjacent serial numbers to an area of one of the sub-pixels is 1/M; when i=3, a ratio of an area of an overlapping zone of light-emitting zones of two sub-pixels having adjacent serial numbers to an area of a light-emitting zone of one of the sub-pixels is ⅔, and a ratio of an area of an overlapping zone of light-emitting zones of two sub-pixels having adjacent serial numbers to an area of one of the sub-pixels is 2/M; when i=4, a ratio of an area of an overlapping zone of light-emitting zones of two sub-pixels having adjacent serial numbers to an area of a light-emitting zone of one of the sub-pixels is ¾, and a ratio of an area of an overlapping zone of light-emitting zones of two sub-pixels having adjacent serial numbers to an area of one of the sub-pixels is 3/M; when i=M−1, a ratio of an area of an overlapping zone of light-emitting zones of two sub-pixels having adjacent serial numbers to an area of a light-emitting zone of one of the sub-pixels is (M−2)/(M−1), and a ratio of an area of an overlapping zone of light-emitting zones of two sub-pixels having adjacent serial numbers to an area of one of the sub-pixels is (M−2)/M; and so on.

Then, with the light-splitting structure as a cylindrical lens, K=2, M=3 and n=10 as examples, parameter designs of the light-splitting structure in the display apparatus provided in the embodiment of the present disclosure are introduced. During specific implementation, for example, the display apparatus includes 1080×1920 pixel islands, P1=116.4 μm, P2=77.6 μm, and L1=400 mm. According to

$$D = ( \frac{1}{2} + m ) W ,$$

m=0, and when D=65 mm, W=2*D=130 mm. The spacer dielectric layer is generally made of glass, and n3=1.5. L1=400 mm, W=130 mm, n3=1.5 and P2=77.6 μm are substituted into

$$H = \frac{n 3 L 1}{W} \times P 2 ,$$

and H=507 mm is obtained.

During specific implementation, if n1=1.55, n2=1.42, and n3=1.5, H=507 mm, and

$$r = \frac{( n 1 - n 2 ) H}{n 3} = 43.94 μm .$$

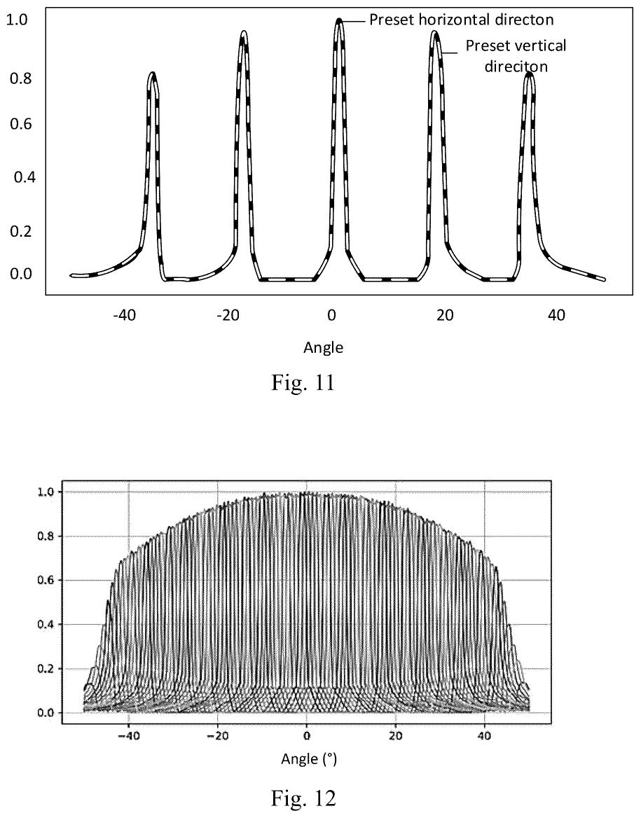

Then, a simulation result of a radius of curvature of the cylindrical lens under the condition that the radius of curvature of the cylindrical lens is greater than or equal to 0.9 r and smaller than or equal to 1.24 r is introduced. According to the above computed parameters: P2=77.6 μm, H=537 mm, and r=43.94 μm, modeling is conducted, and then the radius of curvature is scanned, where the radius of curvature is 47 μm, such that a light-emitting angular spectrum of the sub-pixel numbered 10 under the condition of the radius of curvature of 47 μm as shown in FIG. 11 is obtained. It may be seen from FIG. 11 that angular spectra of the preset horizontal direction and the preset vertical direction are completely coincident, such that a technical effect of 3D compatibility in horizontal and vertical directions may be achieved. FIG. 12 shows distribution of angular spectra of 20 sub-pixels in a horizontal direction, from which crosstalk conditions between all viewpoints may be computed. Primary crosstalk (crosstalk between adjacent viewpoints) is 35.92%-78.09%, and secondary crosstalk (crosstalk between spaced viewpoints) is 8.11%-11.27%. It may be seen that crosstalk drops sharply after the secondary crosstalk. At the optimal viewing distance (L1=400 mm), crosstalk between left and right eyes is level 10 crosstalk, and crosstalk between the left and right eyes is 0, such that a desirable 3D display effect is achieved. Simulation is conducted according to distribution of crosstalk between left and right eyes corresponding to the above parameters in the whole visible space, and limitation and control are conducted according to a crosstalk standard within 10%, such that the 3D visible space is 300 mm-1400 mm in a vertical direction and −14.7°-14.7° in a horizontal direction. Limitation and control are conducted according to a crosstalk standard within 3%, such that the 3D visible space is 300 mm-700 mm in a vertical direction and −6°-6° in a horizontal direction. Limitation and control are conducted according to a crosstalk standard within 1%, such that the 3D visible space is 300 mm-500 mm in a vertical direction and −2.1°-2.1° in a horizontal direction. That is, when the first direction is parallel to the column direction, 3D display with low crosstalk may be achieved.

In some embodiments, sub-pixels include sub-pixel aperture zones, and zones of the sub-pixels 08 shown in FIGS. 1 and 8 are corresponding sub-pixel aperture zones. As shown in FIGS. 1 and 8, each sub-pixel aperture zone is in a shape of a rectangle; and two pairs of sides of the rectangle are parallel to the row direction x and the column direction y respectively.

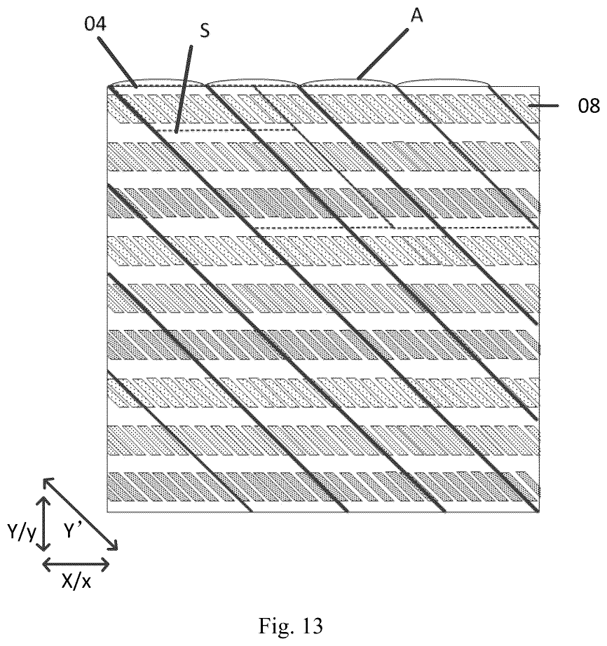

Alternatively, in some embodiments, as shown in FIG. 13, the zones of the sub-pixels 08 are the corresponding sub-pixel aperture zones, and each sub-pixel aperture zone is in a shape of a parallelogram; and one pair of sides of the parallelogram are parallel to the row direction x, and the other pair of sides of the parallelogram are parallel to the first direction Y′.

In FIGS. 13, K=2, M=3, and n=10. In FIG. 13, the row direction x is parallel to the preset horizontal direction X, the column direction y is parallel to the preset vertical direction Y, and the included angle between the first direction Y′ and the preset vertical direction Y is 45°. An aperture ratio of sub-pixels is ⅔.

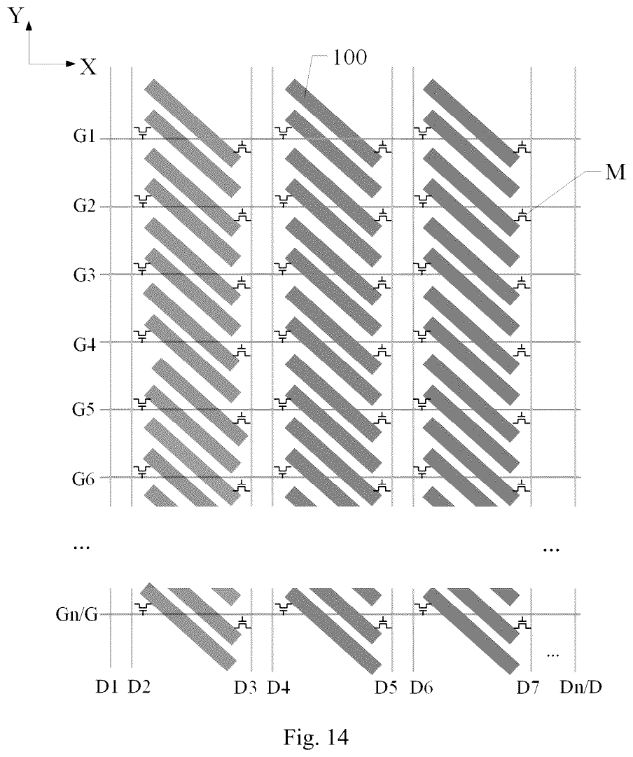

FIG. 14 is a schematic diagram of a pixel connection structure of a display panel. For example, as shown in FIG. 14, the display panel includes a plurality of sub-pixels 100, the plurality of sub-pixels 100 are arrayed in arrays in the row direction X and the column direction Y. The display panel also includes a plurality of data lines D, a plurality of scanning lines G, and a plurality of switching elements M. The plurality of data lines D, such as data line D1, data line D2, . . . data line D7, etc., are arranged at intervals in the row direction X, and each data line D is configured to transmit data signals. The plurality of scanning lines G, such as scanning line G1, scanning line G2, scanning line G7, etc., arranged at intervals in the column direction Y, and each scanning line G is configured to transmit scanning signals. For example, the scanning signal may be a gate signal, but is not limited thereto. For example, the switching element M can be a thin film transistor. For example, the plurality of switching elements M correspond to the plurality of sub-pixels 100 one by one. One sub-pixel 100 is connected with one data line D and one scanning line G through one switching element M; and the sub-pixel 100 can emit light driven by the data signal and the scanning signal.

For example, as shown in FIG. 14, two sub-pixels 100 adjacent to each other in the column direction Y are connected with the same scanning line G, and the two sub-pixels 100 are respectively connected with two adjacent data lines D. Thus, compared with the connection mode in which one sub-pixel 100 corresponds to one scanning line G, the connection mode shown in FIG. 14 can effectively reduce the number of scanning lines G, thereby increasing the refresh rate of the display panel. In some embodiment of the disclosure, the row direction X and the column direction Y intersect with each other, and the row direction X and the column direction Y are parallel to the display surface of the display panel, for example, the row direction X is perpendicular to the column direction Y.

However, in the study, the inventor of the disclosure found that when the connection mode shown in FIG. 14 is adopted, when the scanning signal is applied to a scanning line G (such as scanning line G1), since two adjacent sub-pixels 100 in the column direction Y are connected with two data lines D (such as data line D1 and data line D2) respectively, the data signals transmitted by the two data lines D may be different, for example, different gray scale signals may be transmitted in the two adjacent sub-pixels 100, so the two adjacent sub-pixels 100 may have different light emission conditions, which makes it difficult to realize the merging function of the two sub-pixels 100. In some embodiment of the present disclosure, the combination of multiple sub-pixels means that the multiple sub-pixels can receive the same data signal to have the same gray scale information.

At least one embodiment of the present disclosure provides a display panel including a plurality of pixel groups, a plurality of data lines, and a plurality of scanning lines, where the plurality of pixel groups arranged in arrays in the row direction and the column direction, each pixel group includes a plurality of sub-pixels; the plurality of data lines are arranged at intervals in the row direction, each data line extending in the column direction, and the column direction intersect with the row direction; the plurality of scanning lines are arranged at intervals in the column direction, and each scanning line extending in the row direction. The plurality of sub-pixels in the pixel group include a first sub-pixel, a second sub-pixel, a third sub-pixel, and a fourth sub-pixel sequentially arranged in the column direction, the plurality of scanning lines include a first scanning line and a second scanning line adjacent to each other in the column direction, the first scanning line is configured to apply a first scanning signal to the first sub-pixel and the third sub-pixel, the second scanning line is configured to apply a second scanning signal to the second sub-pixel and the fourth sub-pixel. The plurality of data lines includes a first data line and a second data line adjacent to each other in the row direction, the first data line is configured to apply a first data signal to the third sub-pixel and the fourth sub-pixel, and the second data line is configured to apply a second data signal to the first sub-pixel and the second sub-pixel.

In the display panel provided in at least one embodiment of the present disclosure, when a scanning signal is applied to the first scanning line and the second scanning line adjacent to each other, on the one hand, the first data signal can be applied to the third sub-pixel and the fourth sub-pixel adjacent to each other, and the second data signal can be applied to the first sub-pixel and the second sub-pixel adjacent to each other, thereby enabling a merging function of the first sub-pixel and the second sub-pixel and a merging function of the third sub-pixel and the fourth sub-pixel. On the other hand, the first scanning signal can be applied to the first sub-pixel and the third sub-pixel, and the second scanning signal can be applied to the second sub-pixel and the fourth sub-pixel, thereby effectively reducing the number of scanning lines in the display panel, and thereby increasing the refresh frequency.

The display panel and the display device provided in at least one embodiment of the present disclosure are described in more detail below in conjunction with the accompanying drawings, so as to make the corresponding technical solutions clearer and easier to understand.

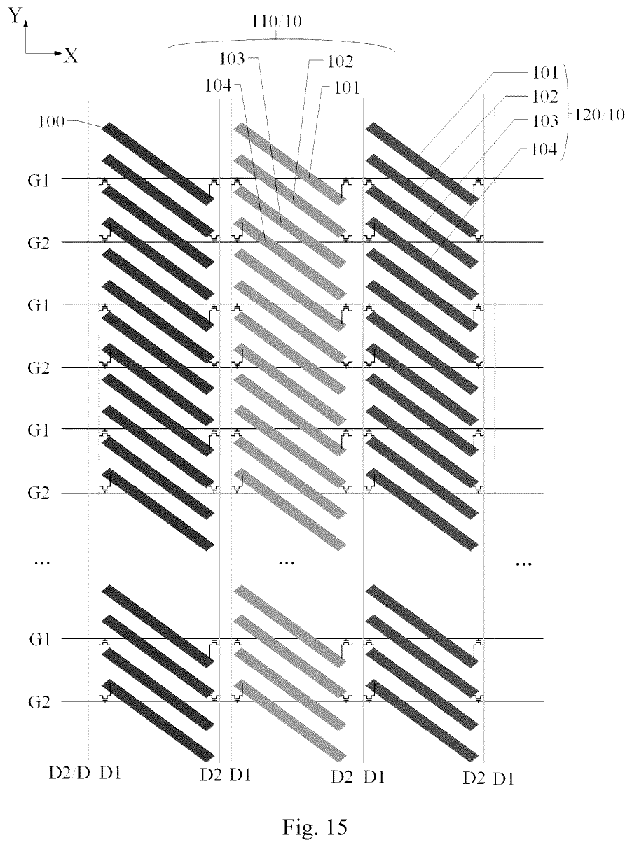

FIG. 15 is a schematic diagram of a pixel connection structure of a display panel provided by at least one embodiment of the present disclosure.

As shown in FIG. 15, the display panel includes a plurality of pixel groups 10 arranged in arrays in the row direction X and the column direction Y. Each pixel group 10 includes a plurality of sub-pixels 100, and the plurality of sub-pixels 100 includes the first sub-pixel 101, the second sub-pixel 102, the third sub-pixel 103 and the fourth sub-pixel 104 arranged in the column direction Y, that is, a plurality of sub-pixels 100 in the same pixel group 10 are located in the same column.

As shown in FIG. 15, the display panel includes a plurality of data lines D, which are arranged at intervals in the row direction X, and each data line D extends along the column direction Y. The plurality of data lines D include a first data line D1 and a second data line D2 adjacent to each other in the row direction X. The first data line D1 is configured to apply the first data signal to the third sub-pixel 103 and the fourth sub-pixel 104 in the pixel group 10, and the second data line D2 is configured to apply the second data signal to the first sub-pixel 101 and the second sub-pixel 102 in the pixel group 10. That is, the first sub-pixel 101 and the second sub-pixel 102 adjacent to each other in the column direction Y receive the second data signal from the second data line D2, so that the first sub-pixel 101 and the second sub-pixel 102 have the same gray scale information, so as to facilitate the merging function of the first sub-pixel 101 and the second sub-pixel 102. The third sub-pixel 103 and the fourth sub-pixel 104 adjacent to each other in the column direction Y receive the first data signal from the first data line D1, so that the third sub-pixel 103 and the fourth sub-pixel 104 have the same gray scale information, so as to facilitate the merging function of the third sub-pixel 103 and the fourth sub-pixel 104.

As shown in FIG. 15, the display panel includes a plurality of scanning lines G, which are arranged at intervals in the column direction Y, and each scanning line G extends along the row direction X. The plurality of scanning lines G include a first scanning line G1 and a second scanning line G2 adjacent to each other in the column direction Y. The first scanning line G1 is configured to apply a first scanning signal to the first sub-pixel 101 and the third sub-pixel 103, and the second scanning line G2 is configured to apply a second scanning signal to the second sub-pixel 102 and the fourth sub-pixel 104. Thus, the first sub-pixel 101 and the third sub-pixel 103 receive the first scanning signal from the first scanning line G1, and the second sub-pixel 102 and the fourth sub-pixel 104 receive the second scanning signal from the second scanning line G2. By setting this, the number of scanning lines G in the display panel can be reduced, and the refresh rate can be increased.

In a display panel provided in at least one embodiment of the present disclosure, when the scanning signals are applied to the first scanning line and the second scanning line adjacent to each other, on the one hand, the first data signal can be applied to the third sub-pixel and the fourth sub-pixel adjacent to each other, and the second data signal can be applied to the first sub-pixel and the second sub-pixel adjacent to each other, thereby achieving the merging function of the first sub-pixel and the second sub-pixel, as well as the merging function of the third sub-pixel and the fourth sub-pixel. On the other hand, the first scanning signal can be applied to the first sub-pixel and the third sub-pixel, and the second scanning signal can be applied to the second sub-pixel and the fourth sub-pixel, thereby effectively reducing the number of scanning lines in the display panel, and increasing the refresh frequency.

The display panel provided by the embodiment of the present disclosure can perform intelligent regulation on the pixel circuit, for example, the display panel can perform 2D display or 3D display, and can also perform 2D display and 3D display in different areas at the same time, so as to realize the sub domain display of the display panel, thus better realize the full use of data and meet the efficient transmission of information.

In some embodiments, as shown in FIG. 15, when performing 2D display, taking one pixel group 10 as an example, the first scanning line G1 and the second scanning line G2 corresponding to the pixel group 10 can be turned on at the same time. At this time, the first sub-pixel 101 and the second sub-pixel 102 have the same gray scale information to facilitate the merging function of the first sub-pixel 101 and the second sub-pixel 102. The third sub-pixel 103 and the fourth sub-pixel 104 have the same gray scale information, so as to facilitate the merging function of the third sub-pixel 103 and the fourth sub-pixel 104. For example, for two adjacent pixel groups 10 in column direction Y, the two pixel groups 10 correspond to the same first data line D1 and the same second data line D2, the two pixel groups 10 correspond to two different first scanning lines G1 and two different second scanning lines G2. The four scanning lines G corresponding to the two pixel groups 10 can be turned on at the same time, so that two first sub-pixels 101 and two second sub-pixels 102 in the two pixel groups 10 have the same gray scale information, and the two third sub-pixels 103 and two fourth sub-pixels 104 in the two pixel groups 10 have the same gray scale information. Of course, according to different display requirements, two adjacent scanning lines G located at a specific position can be turned on at the same time, which is not limited by the embodiment of the present disclosure.

In some embodiments, as shown in FIG. 15, when 3D display is performed, the first scanning line G1 and the second scanning line G2 corresponding to the pixel group 10 can be turned on line by line. For example, the first scanning line G1 can be turned on before the second scanning line G2, so that the first sub-pixel 101, the second sub-pixel 102, the third sub-pixel 103 and the fourth sub-pixel 104 can respectively display different gray scale information.

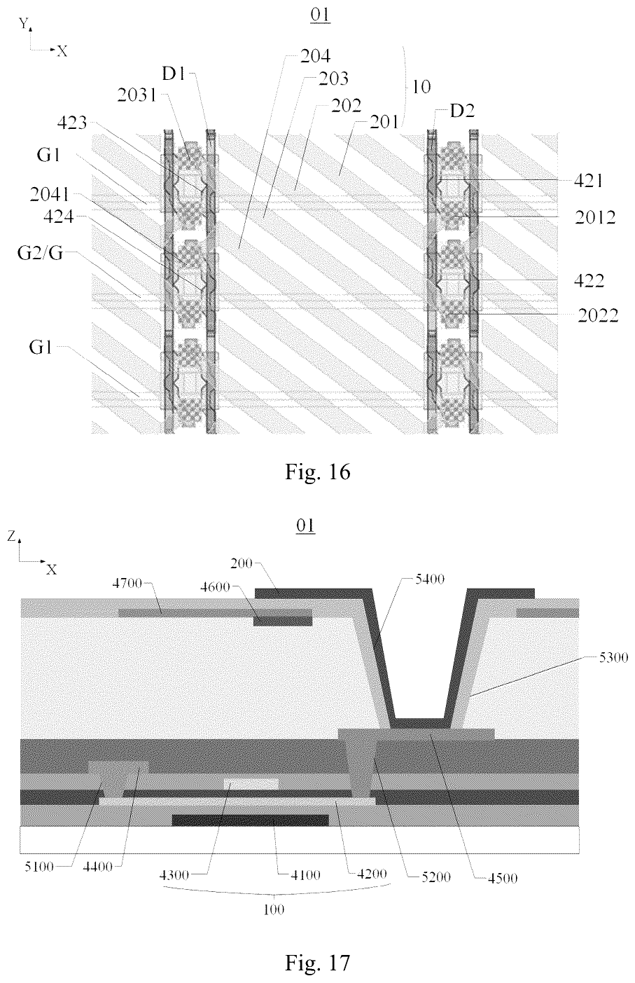

FIG. 16 is a schematic diagram of a partial structure of a display panel provided by at least one embodiment of the present disclosure. FIG. 17 is a schematic diagram of a partial cross-section corresponding to the display panel of FIG. 16.

In some embodiments, as shown in FIG. 16 and FIG. 17, the display panel 01 includes the base substrate BS, and the buffer layer BF, the gate insulation layer G1, the first interlayer dielectric layer ILD1, the second interlayer dielectric layer ILD2, the planarization layer PLN and the passivation layer PVX arranged in turn in the third direction Z perpendicular to the base substrate BS. For example, the display panel 01 also includes a first conductive structure 4100, an active structure 4200, a second conductive structure 4300, a third conductive structure 4400, a fourth conductive structure 4500, a common electrode 4700, and a pixel electrode 200 corresponding to each sub-pixel 100.

In some embodiments, as shown in FIG. 17, the first conductive structure 4100 is arranged on and in contact with the base substrate BS, the active structure 4200 is arranged on and in contact with the buffer layer BF, and the second conductive structure 4300 is arranged on and in contact with the gate insulation layer G1. For example, the first conductive structure 4100 can be used as the light shielding structure, the second conductive structure 4300 can be used as the gate electrode of the sub-pixel, and the third conductive structure 4400 can be used as the source electrode of the sub-pixel 100, and the source electrode can be connected with the active structure 4200 through the first through hole 5100. For example, the fourth conductive structure 4500 can be used as the drain electrode of the sub-pixel 100, and the drain electrode can be connected with the active structure 4200 through the second through hole 5200 that runs through the first interlayer dielectric layer ILD1 and the second interlayer dielectric layer ILD2. The common electrode 4700 is arranged on and in contact with the planarization layer PLN, and the pixel electrode 200 is arranged on and in contact with the passivation layer PVX. For example, the side of the pixel electrode 200 facing away from the base substrate BS is also provided with a liquid crystal layer (not shown in the figure). An electric field that drives the liquid crystal molecules to deflect can be formed between the pixel electrode 200 and the common electrode 4700 to enable the display panel to display. In some embodiments, in order to reduce the resistance of the common electrode 4700, the display panel 01 also includes an auxiliary electrode 4600, which is arranged between the common electrode 4700 and the planarization layer PLN, and the auxiliary electrode 4600 is connected with the common electrode 4700.

It is understood that the structure of the display panel provided in the embodiments of the present disclosure is not limited to the structure shown in FIGS. 16 and 17, and the structure of each film layer in the display panel can be flexibly set according to the needs, and the embodiments of the present disclosure are not limited thereto. The common electrode is not shown in FIG. 16 for the sake of clarity; and the structure of the common electrode can be described in FIGS. 17 and 30 (see subsequent embodiments).

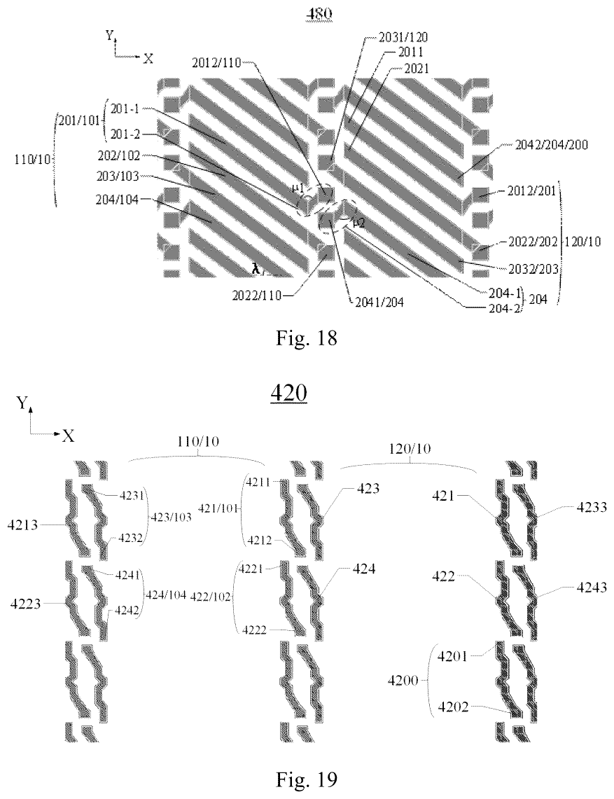

FIG. 18 is a schematic diagram of the pixel electrode pattern corresponding to the display panel of FIG. 16.

In some embodiments, as shown in FIGS. 16 and 18, each sub-pixel 100 (see FIG. 15) in the display panel 01 includes a pixel electrode 200. For example, each sub-pixel 100 includes one pixel electrode 200. For example, the first sub-pixel 101 includes the first pixel electrode 201, the second sub-pixel 102 includes the second pixel electrode 202, the third sub-pixel 103 includes the third pixel electrode 203, and the fourth sub-pixel 104 includes the fourth pixel electrode 204. The first pixel electrode 201, the second pixel electrode 202, the third pixel electrode 203, and the fourth pixel electrode 204 are arranged in the same column, and are sequentially arranged in the column direction Y. The pixel electrode 200 is a part of the sub-pixel 100, and the pixel electrode 200 can also include a pixel driving structure, for example, the pixel driving structure can include the gate electrode of the sub-pixel 100 (see the second conductive structure 4300 in FIG. 17), the source electrode of the sub-pixel 100 (see the third conductive structure 4400 in FIG. 17), and the drain electrode of the sub-pixel 100 (see the fourth conductive structure 4500 in FIG. 17).

In some embodiments, as shown in FIG. 18, each pixel electrode 200 includes a first end and a second end arranged opposite to each other. For example, the first end and the second end of the pixel electrode 200 are two ends of the pixel electrode 200 near two edge regions thereof, respectively. For example, the pixel electrode 200 may have a bending portion between the first end and the second end. For example, the first pixel electrode 201 includes a first end 2011 and a second end 2012 arranged opposite to each other, the second pixel electrode 202 includes a first end 2021 and a second end 2022 arranged opposite to each other, the third pixel electrode 203 includes a first end 2031 and a second end 2032 arranged opposite to each other, and the fourth pixel electrode 204 includes a first end 2041 and a second end 2042 arranged opposite to each other. For example, in the same pixel group 10 (e.g., the first pixel group 110), the first pixel electrode 201 and the fourth pixel electrode 204 are in a mirror image symmetric structure, and the second pixel electrode 202 and the third pixel electrode 203 in the pixel group 10 are in a mirror image symmetric structure. This setting can make the distribution of the pixel electrodes 200 in the pixel groups more orderly, and is conducive to simplifying the structure of the pixel electrodes 200.

In some embodiments, as shown in FIG. 18, the first pixel electrode 201, the second pixel electrode 202, the third pixel electrode 203, and the fourth pixel electrode 204 are arranged at intervals, and angles between the main body extension directions of the first pixel electrode 201, the second pixel electrode 202, the third pixel electrode 203, and the fourth pixel electrode 204 and the row direction X is greater than 0; and angles between the main body extension directions of the first pixel electrode 201, the second pixel electrode 202, the third pixel electrode 203, and the fourth pixel electrode 204 and the column direction Y are greater than 0. That is, the angle between the main body extension direction of the first pixel electrode 201 and the row direction X is greater than 0, and the angle between the main body extension direction of the first pixel electrode 201 and the column direction Y is greater than 0. The angle between the main body extension direction of the second pixel electrode 202 and the row direction X is greater than 0, and the angle between the main body extension direction of the second pixel electrode 202 and the column direction Y is greater than 0. The angle between the main body extension direction of the third pixel electrode 203 and the row direction X is greater than 0, and the angle between the main body extension direction of the third pixel electrode 203 and the column direction Y is greater than 0. The angle between the main body extension direction of the fourth pixel electrode 204 and the row direction X is greater than 0, and the angle between the main body extension direction of the fourth pixel electrode 204 and the column direction Y is greater than 0. Where, the main body extension direction of the first pixel electrode 201, the main body extension direction of the second pixel electrode 202, the main body extension direction of the third pixel electrode 203, and the main body extension direction of the fourth pixel electrode 204 can be the same, and the main body extension direction of each pixel electrode is same as the first direction.

As shown in FIG. 18, the main body extension direction of each pixel electrode 200 towards the counterclockwise direction has an angle λ with the row direction X. For example, the main body extension direction of the pixel electrode 200 refers to the approximate extension direction of the main body portion of the pixel electrode 200. For example, the pixel electrode 200 can include a local structure that is different from the extension direction of the main body portion, and the extension direction of the local structure is not used as a reference for the main body extension direction. For example, the main body extension directions of the first pixel electrode 201, the second pixel electrode 202, the third pixel electrode 203, and the fourth pixel electrode 204 are the same, and the main body extension directions towards the counterclockwise direction has an angle λ with the row direction X. For example, the above angle λ can be 0 to 90 degrees, such as 10 to 80 degrees, 20 to 70 degrees, 30 to 50 degrees, 40 to 45 degrees, 52 to 55 degrees, 53 to 59 degrees or 60 to 65 degrees, but the embodiments of the present disclosure are not limited to this.

In some embodiments, the display panel provided in embodiments of the present disclosure may include a liquid crystal layer, and since the difference in the birefringence of the liquid crystal molecules in the liquid crystal layer is usually large, which may lead to the problem of color deviation, the pixel electrodes tilted with respect to the row direction can be used to make the liquid crystal molecules fall back in different directions after applying a voltage, so that the effect seen by an observer from various directions tends to be the same, which can help improve the above color deviation problem and improve the viewing angle characteristics.

It will be appreciated that in some embodiments, the main body extension directions of the first pixel electrode, the second pixel electrode, the third pixel electrode, and the fourth pixel electrode may also be different, and the embodiments of the present disclosure are not limited thereto.

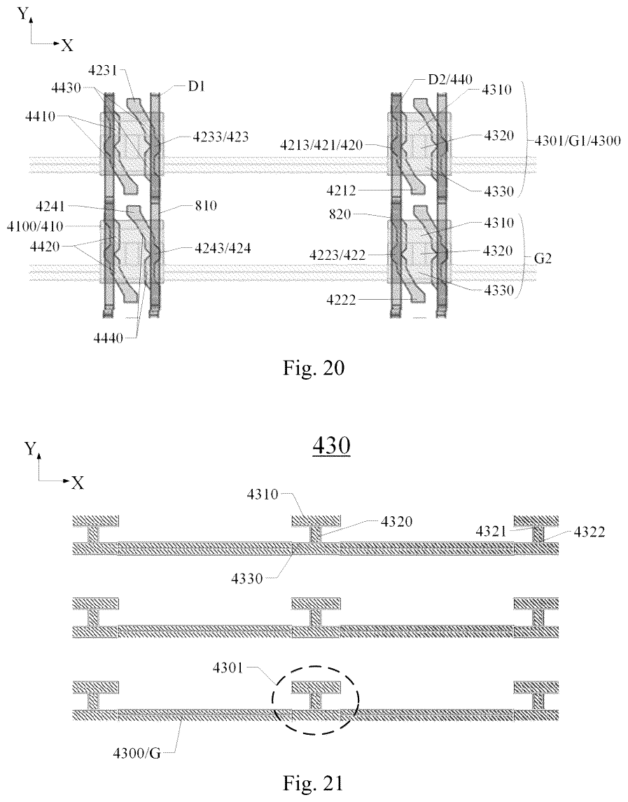

FIG. 19 is a schematic diagram of the active pattern corresponding to the display panel of FIG. 16. FIG. 20 is a schematic diagram of a stacking structure of a first conductive pattern, an active pattern, a second conductive pattern, and a third conductive pattern corresponding to the display panel of FIG. 16.

In some embodiments, as shown in FIGS. 16 and 19, the display panel 01 also includes an active pattern 420, which includes an active structure 4200 corresponding to each sub-pixel (see FIG. 15). For example, active structure 4200 extends in column direction Y. The extension direction of the active structure 4200 refers to the extension direction of the main body of the active structure 4200. The active structure 4200 can include a local structure (for example, a bending structure, etc.) that extends along a direction different from the main body extension direction. Therefore, the extension direction of the local structure is not a reference for the main body extension direction of the active structure 4200. For example, as shown in FIG. 19, the active structure 4200 includes the first connecting end 4201 and the second connecting end 4202 arranged opposite to each other. For example, one of the first connecting end 4201 and the second connecting end 4202 is configured to connect with the pixel electrode 200, and the other of the first connecting end 4201 and the second connecting end 4202 is configured to connect with the drain electrode (and data line D) of the sub-pixel. For example, the drain electrode of the sub-pixel can be integrated with the data line D. For example, the drain electrode of the sub-pixel can also be part of the data line D. Thus, the other of the first connecting end 4201 and the second connecting end 4202 can be directly connected with the data line D.

In some embodiments, as shown in FIG. 19, the first sub-pixel 101 includes the first active structure 421, the second sub-pixel 102 includes the second active structure 422, the third sub-pixel 103 includes the third active structure 423, and the fourth sub-pixel 104 includes the fourth active structure 424. The first active structure 421, the second active structure 422, the third active structure 423, and the fourth active structure 424 are arranged in arrays in the row direction X and the column direction Y, and form an array structure with two rows and two columns. For example, the first active structure 421 and the third active structure 423 are located in the first row of the array structure, the second active structure 422 and the fourth active structure 424 are located in the second row of the array structure, the third active structure 423 and the fourth active structure 424 are located in the first column of the array structure, and the first active structure 421 and the second active structure 422 are located in the second column of the array structure.

In some embodiments, as shown in FIGS. 17 and 20, the first conductive pattern 410 includes a plurality of first conductive structures 4100 corresponding to a plurality of sub-pixels 100, the active pattern 420 includes a plurality of active structures 4200 corresponding to a plurality of sub-pixels 100, and the active structure 4200 overlaps at least partially with the first conductive structure 4100. The second conductive pattern 430 includes a plurality of second conductive structures 4300, for example, the second conductive structure 4300 can be used as the scanning line G. For example, the part where the active structure 4200 overlaps the first conductive structure 4100 overlaps the second conductive structure 4300. The third conductive pattern 440 includes a plurality of third conductive structures 4400, for example, the third conductive structure 4400 can be used as the data line D, and the third conductive structure 4400 intersects with the second conductive structure 4300.

In some embodiments, as shown in FIGS. 19 and 20, in the same pixel group 10, the first connecting end 4211 of the first active structure 421 and the first connecting end 4221 of the second active structure 422 are connected with the second data line D2, the second connecting end 4232 of the third active structure 423 and the second connecting end 4242 of the fourth active structure 424 are connected with the first data line D1. Thus, the first sub-pixel 101 and the second sub-pixel 102 can be allowed to receive the second data signal from the second data line D2, and the third sub-pixel 103 and the fourth sub-pixel can be allowed to receive the first data signal from the first data line D1.

In some embodiments, as shown in FIGS. 16 and 19, in the same pixel group 10, the second connecting end 4212 of the first active structure 421 is closer to the second active structure 422 than the first connecting end 4211 of the first active structure 421, and the second connecting end 4212 of the first active structure 421 is connected to the second end 2012 of the first pixel electrode 201. The second connecting end 4222 of the second active structure 422 is far away from the first active structure 421 than the first connecting end 4221, and the second connecting end 4222 of the second active structure 422 is connected with the second end 2022 of the second pixel electrode 202. The first connecting end 4231 of the third active structure 423 is further far away from the fourth active structure 424 than the second connecting end 4232, and the first connecting end 4231 of the third active structure 423 is connected with the first end 2031 of the third pixel electrode 203. The first connecting end 4241 of the fourth active structure 424 is closer to the third active structure 423 than the second connecting end 4242, and the first connecting end 4241 of the fourth active structure 424 is connected with the first end 2041 of the fourth pixel electrode 204.

In this way, the first pixel electrode 201 can receive the second data signal from the second data line D2 through the first active structure 421. The second pixel electrode 202 can receive the second data signal from the second data line D2 through the second active structure 422. The third pixel electrode 203 can receive the first data signal from the first data line D1 through the third active structure 423. And, the fourth pixel electrode 204 can receive the first data signal from the first data line D1 through the fourth active structure 424.

In some embodiments, as shown in FIGS. 16 and 19, in the same pixel group 10, for example, in the row direction X, the first active structure 421 and the third active structure 423 face to each other, and at least part of any one of the first pixel electrode 201, the second pixel electrode 202, and the third pixel electrode 203 is located between the first active structure 421 and the third active structure 423. For example, in the row direction X, the second active structure 422 and the fourth active structure 424 face to each other, and at least part of any one of the second pixel electrode 202, the third pixel electrode 203, and the fourth pixel electrode 204 is located between the second active structure 422 and the fourth active structure 424. In column direction Y, the second active structure 422 and the fourth active structure 424 are located on the same side of the first active structure 421.

In some embodiments, as shown in FIGS. 16 and 19, the first connecting end 4211 and the second connecting end 4212 of the first active structure 421 of the first sub-pixel 101 (see FIG. 15) are respectively located on both sides of the first scanning line G1, so that the connection position of the first connecting end 4211 of the first active structure 421 and the second data line D2, as well as the connection positions of the second connecting end 4212 of the first active structure 421 and the second end 2012 of the first pixel electrode 201, are all staggered from the first scanning line G1, so as to reduce the risk of signal interference between the first scanning signal and the second data signal.

In some embodiments, as shown in FIGS. 16 and 19, the first connecting end 4221 and the second connecting end 4222 of the second active structure 422 of the second sub-pixel 102 (see FIG. 15) are respectively located on both sides of the second scanning line G2, so that the connection position of the first connecting end 4221 of the second active structure 422 and the second data line D2, as well as the connection positions of the second connecting end 4222 of the second active structure 422 and the second end 2022 of the second pixel electrode 202, are all staggered from the second scanning line G2, so as to reduce the risk of signal interference between the second scanning signal and the second data signal.

Similarly, as shown in FIGS. 16 and 19, the first connecting end 4231 and the second connecting end 4232 of the third active structure 423 of the third sub-pixel 103 (see FIG. 15) are located on both sides of the first scanning line G1, so that the risk of signal interference between the first scanning signal and the first data signal can be reduced. The first connecting end 4241 and the second connecting end 4242 of the fourth active structure 424 of the fourth sub-pixel 104 (see FIG. 15) are respectively located on both sides of the second scanning line G2, so that the risk of signal interference between the second scanning signal and the first data signal can be reduced.

In some embodiments, as shown in FIG. 15, the plurality of data lines D in the display panel include a plurality of first data lines D1 and a plurality of second data lines D2, and the plurality of first data lines D1 and the plurality of second data lines D2 are alternately arranged in the row direction X. For example, two second data lines D2 located on both sides of one first data line D1 and adjacent to the first data line D1 respectively correspond to two adjacent pixel groups 10, and the second data line D2 in the two second data lines D2 which is far away from the first data line D1 corresponds to the same pixel group 10 with the one first data line D1.

In some embodiments, as shown in FIG. 15, the plurality of scanning lines G in the display panel include a plurality of first scanning lines G1 and a plurality of second scanning lines G2, and the plurality of first scanning lines G1 and the plurality of second scanning lines G2 are alternately arranged in the column direction Y. For example, the first scanning line G1 on the side of the second scanning line G2 far away from the adjacent first pixel electrode 101 corresponds to the same pixel group 10 with the second scanning line G2. In the embodiments of the present disclosure, “adjacent” refers to being adjacent to each other and closest to each other. For example, the first scanning line G1 adjacent to the second scanning line G2 refers to the first scanning line G1 adjacent to and closest to the second scanning line G2.

In some embodiments, as shown in FIGS. 18 and 20, the second connecting end 4212 of the first active structure 421 and the second connecting end 4222 of the second active structure 422 are both located between the connected second data line D2 and the first data line D1 adjacent to the connected second data line D2, so that the second end 2012 of the first pixel electrode 201 has enough space to connect with the second connecting end 4212 of the first active structure 421. The second end 2022 of the second pixel electrode 202 is convenient for connecting with the second connecting end 4222 of the second active structure 422, and can reduce the risk of signal interference between the second end 2012 of the first pixel electrode 201 and the second end 2022 of the second pixel electrode 202 and the adjacent first data line D1 to each other.

Similarly, as shown in FIGS. 18 and 20, the first connecting end 4231 of the third active structure 423 and the first connecting end 4241 of the fourth active structure 424 are both located between the connected first data line D1 and the second data line D2 adjacent to the connected first data line D1, so that the first end 2031 of the third pixel electrode 203 has enough space to connect with 4231 of the first connecting end of the third active structure 423, and facilitating the connection of the first end 2041 of the fourth pixel electrode 204 with the first connecting end 4241 of the fourth active structure 424, and reducing the risk of signal interference between the first end 2031 of the third pixel electrode 203 and the first end 2041 of the fourth pixel electrode 204 and the adjacent second data line D2.

In some embodiments, as shown in FIG. 20, the first data line D1 corresponding to one pixel group 10 (see FIG. 16) has an edge 810 close to the second data line D2, the second data line D2 has an edge 820 close to the first data line D1, and the edge 810 and the edge 820 are adjacent to each other and arranged opposite to each other in the row direction X. The first active structure 421 and the second active structure 422 overlap with the edge 810, and the third active structure 423 and the fourth active structure 424 overlap with the edge 820. For example, in the direction where the edge 820 points to the edge 810, neither the first active structure 421 nor the second active structure 422 extends beyond the edge 820 of the second data line D2. In the direction where the edge 810 points to the edge 820, neither the third active structure 423 nor the fourth active structure 424 extends beyond the edge 810 of the first data line D1.

This is provided so as to facilitate a larger layout area between the first data line and the second data line corresponding to the same pixel group, thereby facilitating a larger pixel opening ratio to facilitate an improved display effect.

In some embodiments, as shown in FIGS. 16 and 18, in the same pixel group 10, at least part of the second end 2012 of the first pixel electrode 201 is located on the side of the first scanning line G1 close to the second scanning line G2, so as to facilitate connection between the second end 2012 of the first pixel electrode 201 and the second connecting end 4212 of the first active structure 421. At least part of the second end 2022 of the second pixel electrode 202 is located on the side of the second scanning line G2 far away from the first scanning line G1, so as to facilitate the connection between the second end 2022 of the second pixel electrode 202 and the second connecting end 4222 of the second active structure 422. At least part of the first end 2031 of the third pixel electrode 203 is located on the side of the first scanning line G1 far away from the second scanning line G2, so as to facilitate the connection between the first end 2031 of the third pixel electrode 203 and the first connecting end 4231 of the third active structure 423. At least part of the first end 2041 of the fourth pixel electrode 204 is located on the side of the second scanning line G2 close to the first scanning line G1 to facilitate the connection between the first end 2041 of the fourth pixel electrode 204 and the first connecting end 4241 of the fourth active structure 424.

In some embodiments, as shown in FIGS. 16 and 18, the first pixel electrode 201 and the third pixel electrode 203 in the pixel group 10 overlap with the first scanning line G1. At least part of the first end 2011 and the second end 2012 of the first pixel electrode 201 are respectively located on both sides of the first scanning line G1, and at least part of the first end 2031 and the second end 2032 of the third pixel electrode 203 are respectively located on both sides of the first scanning line G1. Such setting is conducive to extending the second end 2012 of the first pixel electrode 201 between the first scanning line G1 and the second scanning line G2, and then connecting with the second connecting end 4212 of the first active structure 421. Also, it is advantageous to extend the first end 2031 of the third pixel electrode 203 to the side of the first scanning line G1 far from the second scanning line G2, and then connect with the first connecting end 4231 of the third active structure 423.

In some embodiments, as shown in FIGS. 16 and 18, the second pixel electrode 202 and the fourth pixel electrode 204 in the pixel group 10 overlap with the second scanning line G2. At least part of the first end 2021 and the second end 2022 of the second pixel electrode 202 are located on both sides of the second scanning line G2, respectively, and at least part of the first end 2021 of the second pixel electrode 202 is located on the side of the first scanning line G1 far away from the second scanning line G2. At least part of the first end 2041 and the second end 2042 of the fourth pixel electrode 204 are respectively located on both sides of the second scanning line G2, and at least part of the second end 2042 of the fourth pixel electrode 204 is located on the side of the second scanning line G2 far away from the first scanning line G1. Such setting is conducive to extending the second end 2022 of the second pixel electrode 202 to the side of the second scanning line G2 far away from the first scanning line G1 to connect with the second connecting end 4222 of the second active structure 422. Also, it is advantageous to extend the first end 2041 of the fourth pixel electrode 204 between the second scanning line G2 and the first scanning line G1 to connect with the first connecting end 4241 of the fourth active structure 424.

In some embodiments, as shown in FIG. 15, a plurality of pixel groups 10 in the display panel include a first pixel group 110 and a second pixel group 120 adjacent to each other in the row direction X. For example, the first pixel group 110 and the second pixel group 120 are respectively located in two adjacent columns of pixels, and the second data line D2 connected with the first pixel group 110 and the first data line D1 connected with the second pixel group 120 are adjacent to each other. The first pixel group 110 and the second pixel group 120 are connected with the same first scanning line G1 and the same second scanning line G2.

In some embodiments, as shown in FIG. 19, in the row direction X, the first active structure 421 in the first pixel group 110 and the third active structure 423 in the second pixel group 120 are arranged in the same row and arranged at intervals, and the second active structure 422 in the first pixel group 110 and the fourth active structure 424 in the second pixel group 120 are arranged in the same row and arranged at intervals. In the row direction X, the distance between the first active structure 421 in the first pixel group 110 and the third active structure 423 in the second pixel group 120 is less than the distance between the first active structure 421 and the third active structure 423 in the first pixel group 110. The distance between the first active structure 421 in the second pixel group 120 and the third active structure 423 in the second pixel group 120 is greater than the distance between the third active structure 423 in the second pixel group 120 and the first active structure 421 in the first pixel group 110.

By setting in this way, sufficient setup space can be reserved for the pixel electrodes in each pixel group to facilitate the increase of the pixel opening ratio.

In some embodiments, as shown in FIG. 19, in the column direction Y, the first active structure 421 and the second active structure 422 in the first pixel group 110 are arranged in the same column and arranged at intervals, and the third active structure 423 and the fourth active structure 424 in the second pixel group 120 are arranged in the same column and arranged at intervals For example, in the column direction Y, the distance between the first active structure 421 in the first pixel group 110 and the second active structure 422 in the first pixel group 110 is basically the same as the distance between the third active structure 423 in the first pixel group 110 and the fourth active structure 424 in the first pixel group 110. Thus, a uniform distance is maintained between the first scanning line G1 overlapped with the first active structure 421 and the third active structure 423 and the second scanning line G2 overlapped with the second active structure 422 and the fourth active structure 424, which is conducive to the uniform setting of multiple scanning lines G in the display panel in the column direction Y.

In some embodiments, as shown in FIG. 18, in the column direction Y, the first end 2031 of the third pixel electrode 203 in the second pixel group 120, the second end 2012 of the first pixel electrode 201 in the first pixel group 110, the first end 2041 of the fourth pixel electrode 204 in the second pixel group 120, and the second end 2022 of the second pixel electrode 202 in the first pixel group 110 are arranged in the same column, and are arranged alternately in sequence.

In some embodiments, as shown in FIGS. 16 and 18, in the column direction Y, the second end 2012 of the first pixel electrode 201 in the first pixel group 110 and the first end 2031 of the third pixel electrode 203 in the second pixel group 120 overlap at least partially with the first scanning line G1. The second end 2022 of the second pixel electrode 202 in the first pixel group 110 and the fourth pixel electrode 2041 in the second pixel group 120 overlap at least partially with the second scanning line G2.

In some embodiments, as shown in FIG. 18, the first pixel electrode 201 includes a first main body portion 201-1 and a first connecting portion 201-2, the first main body portion 201-1 is connected with the first connecting portion 201-2, and an end of the first connecting portion 201-2 that is remote from the first main body portion 201-1 serves as a second end 2012 of the first pixel electrode 201. For example, the extension direction of the first main body portion 201-1 is different from the extension direction of the first connecting portion 201-2, the first main body portion 201-1 of the first pixel electrode 201 is the same as the extension direction of the second pixel electrode 202, and the first connecting portion 201-2 of the first pixel electrode 201 extends in a direction far away from the second pixel electrode 202 adjacent to the first connecting portion 201-2 of the first pixel electrode 201. For example, the angle μ1 between the extension direction of the first connecting portion 201-2 towards a counterclockwise direction and the extension direction of the first main body portion 201-1 ranges from 60 to 120 degrees, such as 70 to 90 degrees, 80 to 100 degrees, or 90 to 110 degrees, and the embodiments of the present disclosure are not limited thereto.

In some embodiments, as shown in FIG. 18, the fourth pixel electrode 204 includes a second main body portion 204-1 and a second connecting portion 204-2, the second main body portion 204-1 is connected with the second connecting portion 204-2, and an end of the second connecting portion 204-2 far away from the second main body portion 204-1 serves as a first end 2041 of the fourth pixel electrode 204. The extension direction of the second main body portion 204-1 of the fourth pixel electrode 204 is different from the extension direction of the second connecting portion 204-2 of the fourth pixel electrode 204. The extension direction of the second main body portion 204-1 of the fourth pixel electrode 204 is the same as the extension direction of the third pixel electrode 203 adjacent to the second main body portion 204-1 of the fourth pixel electrode 204. The second connecting portion 204-2 of the fourth pixel electrode 204 extends in a direction far away from the third pixel electrode 203 adjacent to the second connecting portion 204-2 of the fourth pixel electrode 204. In some embodiments, the angle μ2 between the extension direction of the second connecting portion 204-2 of the fourth pixel electrode 204 towards the counterclockwise direction and the extension direction of the second main body portion 204-1 of the fourth pixel electrode 204 ranges from 60 to 120 degrees, such as 70 to 90 degrees, 80 to 100 degrees, or 90 to 110 degrees, and the embodiments of the present disclosure are not limited thereto.

By making the first pixel electrode include a first connecting portion and making the fourth pixel electrode include a second connecting portion, it is advantageous to realize the connection between the first pixel electrode and the second connecting end of the first active structure and the connection between the fourth pixel electrode and the first connecting end of the fourth active structure. Thus, the pixel electrode can better adapt to the structure and position of the active pattern in the display panel, making the structural design of the pixel electrodes is more flexible.

In some embodiments, as shown in FIG. 18, the angle μ1 between the extension direction of the first main body portion 201-1 towards the counterclockwise and the extension direction of the first connecting portion 201-2 of the first pixel electrode 201 and the angle μ2 between the extension direction of the second connecting portion 204-2 of the fourth pixel electrode 204 towards the counterclockwise and the extension direction of the second main body portion 204-1 are essentially equal. The angle μ1 and the angle μ2 can be ranged from 80 to 90 degrees. In some embodiments, the extension direction of the first main body portion 201-1 of the first pixel electrode 201 may be the same as the extension direction of the second main body portion 204-1 of the fourth pixel electrode 204, and the extension direction of the first connecting portion 201-2 of the first pixel electrode 201 may be the same as the extension direction of the second connecting portion 204-2 of the fourth pixel electrode 204, and the embodiments of the present disclosure will not be limited thereto.

This setting can make the distance between the first connecting portion of the first pixel electrode and the second connecting portion of the fourth pixel electrode uniform. For example, the first connecting portion and the second connecting portion can be distributed basically parallel to each other, which is advantageous for guaranteeing the reliability of the connection between the first pixel electrode and the first active structure, as well as the reliability of the connection between the fourth pixel electrode and the fourth active structure, and reducing the risk of signal crosstalk.

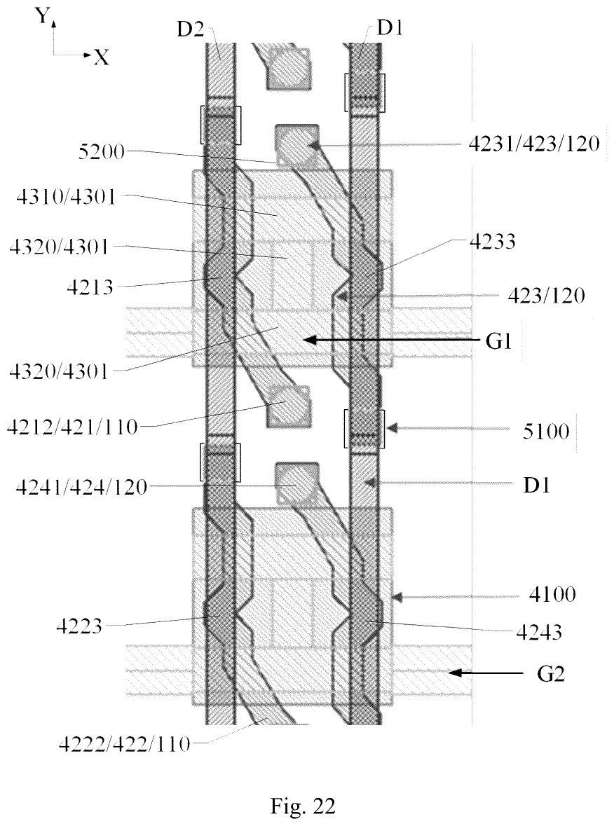

FIG. 21 is a schematic diagram of a second conductive pattern corresponding to the display panel of FIG. 16. FIG. 22 is a schematic diagram of a partial structure of the stacking structure shown in FIG. 20 after the second through hole is provided on the stacking structure.

In some embodiments, as shown in FIG. 21, the second conductive pattern 430 includes a plurality of second conductive structures 4300, which can be used as the scanning line G in the display panel, such as the first scanning line G1 or the second scanning line G2 (see FIG. 15). In some embodiments, the scanning line G includes a connection zone 4301, which includes a first structural portion 4310, a second structural portion 4320, and a third structural portion 4330. The first structural portion 4310 and the third structural portion 4330 are arranged at intervals in the column direction Y, and both extend in the row direction X, the second structural portion 4320 extends in the column direction Y, and one end 4321 of the second structural portion 4320 is connected with the first structural portion 4310, the other end 4322 of the second structural portion 4320 is connected with the third structural portion 4330.

In some embodiments, as shown in FIG. 22, the second connecting end 4212 of the first active structure 421 in the first pixel group 110 and the first connecting end 4231 of the third active structure 423 in the second pixel group 120 are respectively located on both sides of the connection zone 4301 of the first scanning line G1, and the second connecting end 4212 of the first active structure 421 in the first pixel group 110 is located on the side of the third structural portion 4330 far away from the first structural portion 4310. The second connecting end 4222 of the second active structure 422 in the first pixel group 110 and the first connecting end 4241 of the fourth active structure 424 in the second pixel group 120 are respectively located on both sides of the connection zone 4301 of the second scanning line G2, and the first connecting end 4241 of the fourth active structure 424 in the first pixel group 110 is located on the side of the first structural portion 4310 far away from the third structural portion 4330.

In some embodiments, as shown in FIG. 22, the first active structure 421 includes the first bending portion 4213, the second active structure 422 includes the second bending portion 4223, the third active structure 423 includes the third bending portion 4233, and the fourth active structure 424 includes the fourth bending portion 4243. In the column direction Y, the first bending portion 4213 and the third bending portion 4233 are located between the first structural portion 4310 of the first scanning line G1 and the third structural portion 4330 of the first scanning line G1, and the second bending portion 4223 and the fourth bending portion 4243 are located between the first structural portion 4310 of the second scanning line G2 and the third structural portion 4330 of the second scanning line G2.

In some embodiments, as shown in FIG. 22, in the same pixel group 10 (see FIG. 15), the first bending portion 4213 and the third bending portion 4233 are concaved towards the opposite direction, and the second bending portion 4223 and the fourth bending portion 4243 are concaved towards the opposite direction. In some embodiments, in the row direction X, the first bending portion 4213 in the first pixel group 110 and the third bending portion 4233 in the second pixel group 120 are respectively located on both sides of the second structural portion 4320 of the first scanning line G1, and are concaved towards the direction far away from the second structural portion 4320 of the first scanning line G1, so that the second structural portion 4320 of the first scanning line G1 can be avoided. The second bending portion 4223 in the first pixel group 110 and the fourth bending portion 4243 in the second pixel group 120 are respectively located on both sides of the second structural portion 4320 of the second scanning line G2, and are concaved towards the direction far away from the second structural portion 4320 of the second scanning line G2, so that the second structural portion 4320 of the second scanning line G2 can be avoided.

This setting can reduce the risk of signal crosstalk between the first active structure and the third active structure and the second structural portion of the first scanning line, as well as the risk of signal crosstalk between the second active structure and the fourth active structure and the second structural portion of the second scanning line, thereby ensuring the reliability of the transmission of the signals in the connection zone of the first scanning line as well as in the connection zone of the second scanning line.

In some embodiments, as shown in FIG. 22, the first bending portion 4213 in the first pixel group 110 and the third bending portion 4233 in the second pixel group 120 are arranged at intervals with the second structural portion 4320 of the first scanning line G1. The second bending portion 4223 in the first pixel group 110 and the fourth bending portion 4243 in the second pixel group 120 are arranged at intervals with the second structural portion 4320 of the second scanning line G2. The distance between the first bending portion 4213 in the first pixel group 110 and the second structural portion 4320 of the first scanning line G1 is basically the same as the distance between the third bending portion 4233 in the second pixel group 120 and the second structural portion 4320 of the first scanning line G1. The distance between the second bending portion 4223 in the first pixel group 110 and the second structural portion 4320 of the second scanning line G2 is basically the same as the distance between the fourth bending portion 4243 in the second pixel group 120 and the second structural portion 4320 of the second scanning line G2. While ensuring the orderly layout of the layout space, the parasitic capacitance between the first bending portion 4213 and the second structural portions 4320 adjacent to the first bending portion 4213, the parasitic capacitance between the second bending portion 4223 and the second structural portions 4320 adjacent to the second bending portion 4223, the parasitic capacitance between the third bending portion 4233 and the second structural portions 4320 adjacent to the third bending portion 4233, and the parasitic capacitance between the fourth bending portion 4243 and the second structural portions 4320 adjacent to the fourth bending portion 4243 are basically the same.

In some embodiments, as shown in FIG. 22, a portion of the first bending portion 4213 and a portion of the second bending portion 4223 overlap with the second data line D2, and a portion of the third bending portion 4233 and a portion of the fourth bending portion 4243 overlap with the first data line D1. The first bending unit 4213 has a first overlapping portion overlapped with the second data line D2, the second bending unit 4223 has a second overlapping portion overlapped with the second data line D2, the third bending unit 4233 has a third overlapping portion overlapped with the first data line D1, and the fourth bending unit 4243 has a fourth overlapping portion overlapped with the first data line D1.

By overlapping the first bending portion, the second bending portion, the third bending portion, and the fourth bending portion partially with the corresponding data line, the layout space in the row direction can be saved, and the structural setup in the layout can be made more compact.

In some embodiments, as shown in FIG. 22, an orthographic projection of a first overlapping portion of the first bending portion 4213 on the base substrate (see FIG. 17) has a first area; an orthographic projection of a second overlapping portion of the second bending portion 4223 on the base substrate has a second area; an orthographic projection of a third overlapping portion of the third bending portion 4233 on the base substrate has a third area; and an orthographic projection of a fourth overlapping portion of the fourth bending portion 4243 on the base substrate has a fourth area. In some embodiments, the first area is equal to the second area, and the third area is equal to the fourth area, and the embodiments of the present disclosure are not limited thereto.

In some embodiments, as shown in FIG. 22, there is a first ratio between a first area and an orthographic projection area of the first bending portion 4213 on the base substrate, there is a second ratio between a second area and an orthographic projection area of the second bending portion 4223 on the base substrate, there is a third ratio between a third area and an orthographic projection area of the third bending portion 4233 on the base substrate, there is a fourth ratio between a fourth area and an orthographic projection area of the fourth bending portion 4243 on the base substrate. The first ratio, second ratio, third ratio, and fourth ratio are all less than 1. For example, the first ratio, the second ratio, the third ratio, and the fourth ratio are ranged from ⅕ to ½, such as ¼ or ⅓, and the embodiments of the present disclosure are not limited thereto.

This setting is conducive to making the parasitic capacitance between the first bending portion, the second bending portion, the third bending portion and the fourth bending portion and the corresponding data line more uniform, which is conducive to ensuring a good display effect.

In some embodiments, as shown in FIG. 20, the first active structure 421 overlaps at least partially with the first structural portion 4310 and the third structural portion 4330 of the first scanning line G1 adjacent to the first active structure 421 to form the first channel zone 4410. The second active structure 422 overlaps at least partially with the first structural portion 4310 and the third structural portion 4330 of the second scanning line G2 adjacent to the second active structure 422 to form the second channel zone 4420. The third active structure 423 overlaps at least partially with the first structural portion 4310 and the third structural portion 4330 of the first scanning line G1 adjacent to the third active structure 423 to form the third channel zone 4430. The fourth active structure 424 overlaps at least partially with the first structural portion 4310 and the third structural portion 4330 of the second scanning line G2 adjacent to the fourth active structure 424 to form the fourth channel zone 4440. In some embodiments, as shown in FIGS. 19 and 20, the first channel zone 4410 in the first pixel group 110 and the second channel zone 4420 in the second pixel group 120 correspond to the same connection zone 4301, and the third channel zone 4430 in the first pixel group 110 and the fourth channel zone 4440 in the second pixel group 120 correspond to the same connection zone 4301.

In some embodiments, as shown in FIG. 20, the active pattern can include P-type silicon material, and the width length ratio of any one of the first channel zone 4410, the second channel zone 4420, the third channel zone 4430, and the fourth channel zone 4440 is 3:4. However, the embodiments of the present disclosure are not limited to this. The width length ratio of the above channel zone can be flexibly designed by taking into account factors such as manufacturing errors, pixel aperture requirements, and layout design needs. For example, the width length ratio of the channel zone refers to the ratio of the width to the length of the channel zone. For example, the width of the channel zone can be the average size of the channel zone in the row direction X, and the length of the channel zone can be the average size of the channel zone in the column direction Y.

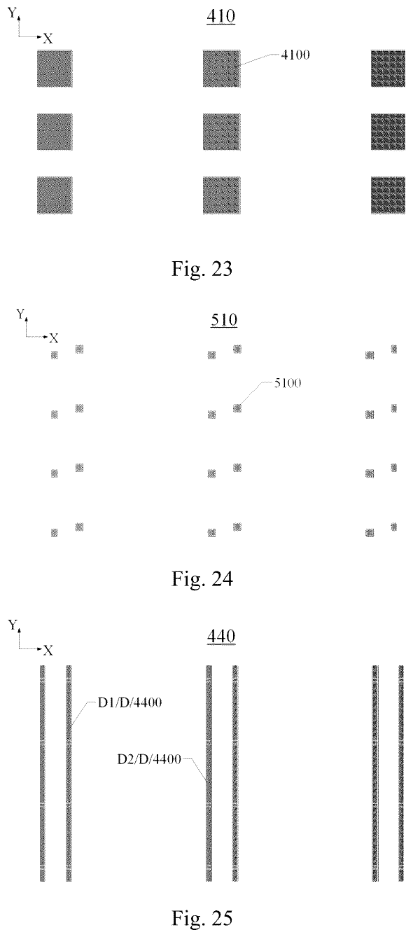

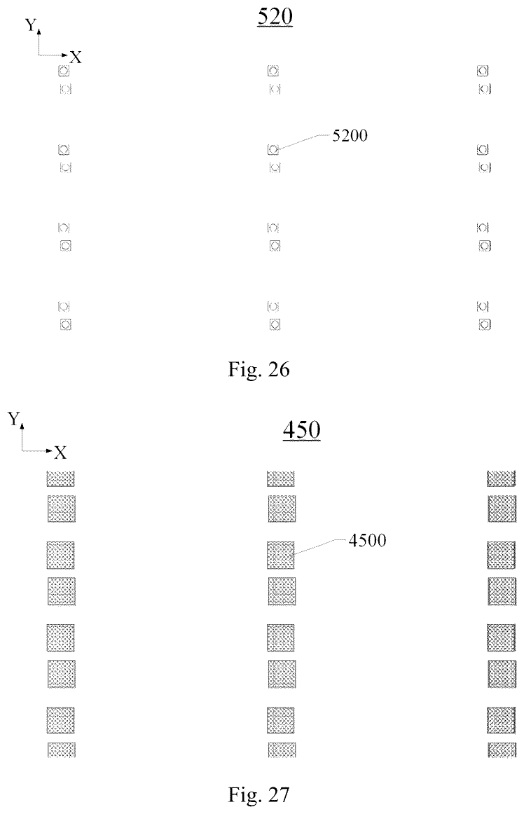

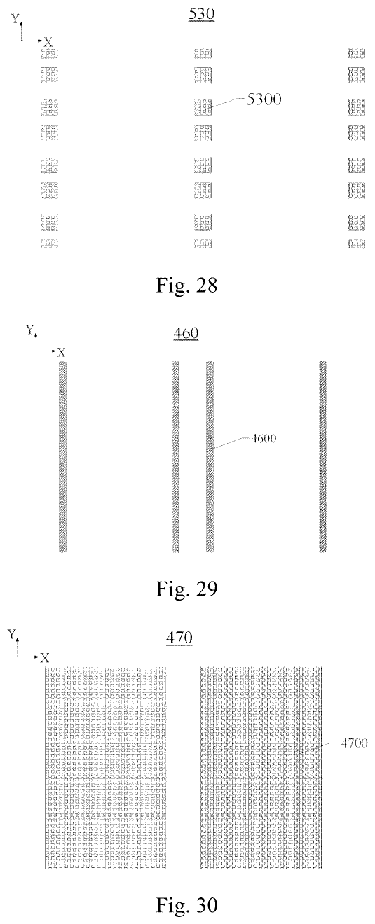

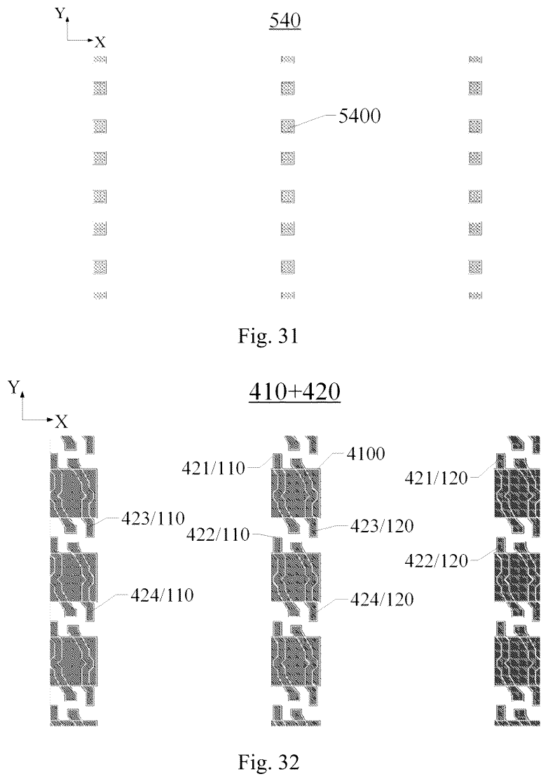

FIG. 23 is a schematic diagram of a first conductive pattern corresponding to the display panel of FIG. 16. FIG. 24 is a schematic diagram of the first through hole pattern corresponding to the display panel of FIG. 16. FIG. 25 is a schematic diagram of a third conductive pattern corresponding to the display panel of FIG. 16. FIG. 26 is a schematic diagram of the second through hole pattern corresponding to the display panel of FIG. 16. FIG. 27 is a schematic diagram of a fourth conductive pattern corresponding to the display panel of FIG. 16. FIG. 28 is a schematic diagram of a third through hole pattern corresponding to the display panel of FIG. 16. FIG. 29 is a schematic diagram of an auxiliary conductive pattern corresponding to the display panel of FIG. 16. FIG. 30 is a schematic diagram of a common electrode pattern corresponding to the display panel of FIG. 16. FIG. 31 is a schematic diagram of a fourth through hole pattern corresponding to the display panel of FIG. 16.

In some embodiments, as shown in FIGS. 17 and 23, the first conductive pattern 410 includes a plurality of first conductive structures 4100, and the plurality of first conductive structures 4100 correspond one-to-one with the plurality of sub-pixels 100 (please refer to FIG. 15).

In some embodiments, as shown in FIG. 17 and FIG. 24, a gate insulation layer G1 and a first interlayer dielectric layer ILD1 are arranged on the active structure 4200, and the first through hole 5100 penetrates the gate insulation layer G1 and the first interlayer dielectric layer ILD1 between the third conductive structure 4400 and the active structure 4200, thereby realizing the connection between the third conductive structure 4400 and the active structure 4200. For example, the plurality of first through holes 5100 correspond to the plurality of sub-pixels one by one.

In some embodiments, as shown in FIG. 25, the third conductive structure 4400 extends along the column direction Y and can be used as data line D, such as the first data line D1 or the second data line D2.

In some embodiments, as shown in FIG. 17, FIG. 26 and FIG. 27, the second interlayer dielectric layer ILD2 is arranged on the first interlayer dielectric layer ILD1, and the second through hole 5200 penetrates the second interlayer dielectric layer ILD2, the first interlayer dielectric layer ILD1 and the gate insulating layer G1 between the fourth conductive structure 4500 and the active structure 4200, thus realizing the connection between the fourth conductive structure 4500 and the active structure 4200.

In some embodiments, as shown in FIGS. 17 and 28, the third through hole 5300 is formed in the planarization layer PLN, and the planarization layer PLN is penetrated to expose at least part of the fourth conductive structure 4500.

In some embodiments, as shown in FIGS. 17 and 29, the auxiliary electrode pattern 460 includes a plurality of auxiliary electrodes 4600, the auxiliary electrodes 4600 extend in the column direction Y. In some embodiments, the auxiliary electrode 460 may include conductive materials. For example, as shown in FIG. 17, part of the auxiliary electrode 4600 is located in the planarization layer PLN, and the other part is located on the side of the planarization layer PLN facing away from the base substrate BS. In some embodiments, the auxiliary electrode 4600 can also be located in the planarization layer PLN, and the surface of the auxiliary electrode 4600 facing away from the base substrate BS is exposed outside the planarization layer PLN to facilitate the connection with the common electrode 4700. The embodiment of this disclosure does not limit the setting form of the auxiliary electrode 4600. Such setting is conducive to reducing the overall size of display panel 01 in column direction Y, so as to facilitate lightweight design.

In some embodiments, as shown in FIGS. 17 and 30, the common electrode pattern 470 includes a plurality of common electrodes 4700, and the size of the common electrode 4700 in the row direction X is larger than the size of the auxiliary electrode 4600 in the row direction X. In some embodiments, as shown in FIG. 17, the orthographic projection of the common electrode 4700 on the base substrate BS overlaps at least partially with the orthographic projection of the auxiliary electrode 4600 on the base substrate BS. In some embodiments, the orthographic projection of the auxiliary electrode 4600 on the base substrate BS can be covered by the orthographic projection of the common electrode 4700 on the base substrate BS, which is not limited by the embodiments of the present disclosure. Such setting is conducive to forming a good electrical connection between the auxiliary electrode 4600 and the common electrode 4700.

In some embodiments, as shown in FIGS. 17 and 31, the fourth through hole 5400 is formed in the passivation layer PVX, and the passivation layer PVX is penetrated. The fourth through hole 5400 is located in the third through hole 5300, and a part of the fourth conductive structure 4500 located in the third through hole 5300 is exposed by the fourth through hole 5400.

In some embodiments, as shown in FIGS. 17 and 18, at least a portion of the pixel electrode 200 is disposed in the fourth through hole 5400 to be connected with the fourth conductive structure 4500, thus the pixel electrode 200 is connected with the active structure 4200 through hole the fourth conductive structure 4500.

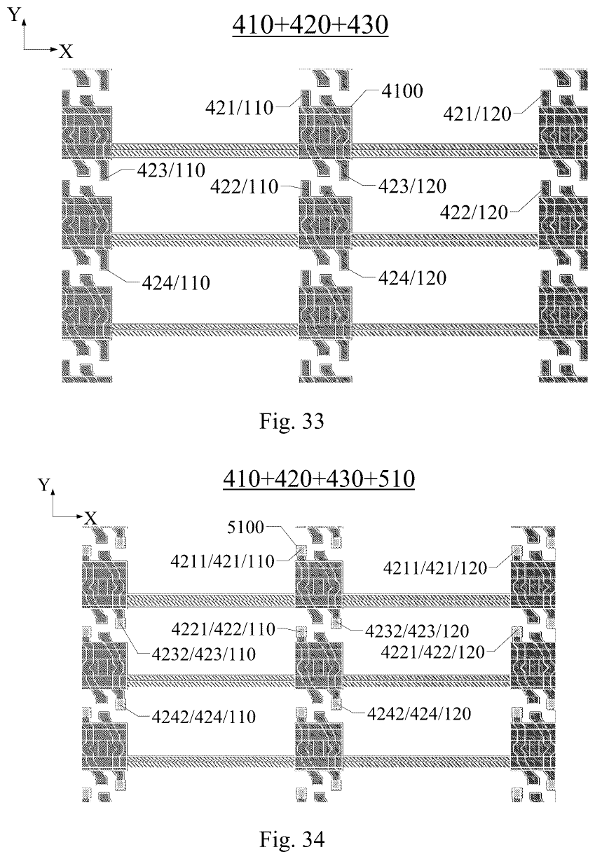

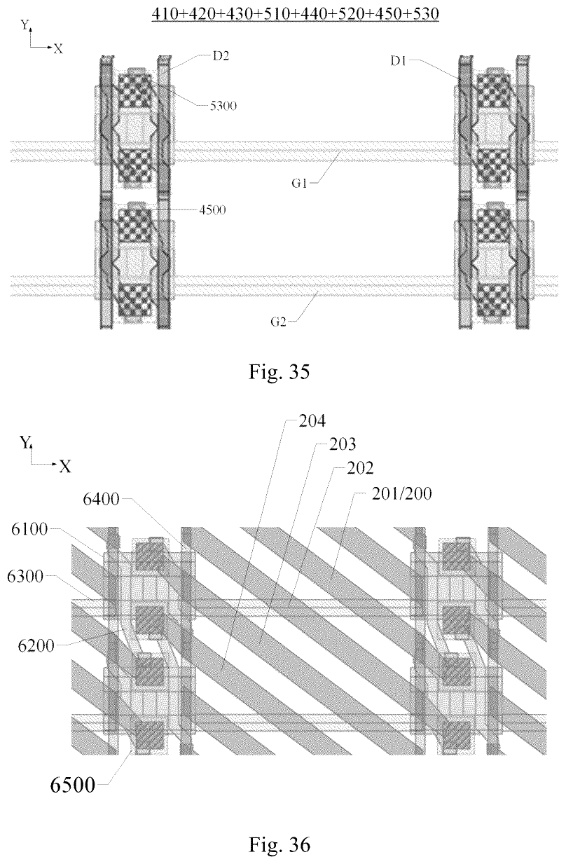

FIG. 32 is a schematic diagram of a stacking structure of a first conductive pattern and an active pattern corresponding to the display panel of FIG. 16. FIG. 33 is a schematic diagram of a stacking structure of a first conductive pattern, an active pattern, and a second conductive pattern corresponding to the display panel of FIG. 16. FIG. 34 is a schematic diagram of a stacking structure of a first conductive pattern, an active pattern, a second conductive pattern, and a first through hole pattern corresponding to the display panel of FIG. 16. FIG. 35 is a schematic diagram of a stacking structure of a first conductive pattern, an active pattern, a second conductive pattern, a third conductive pattern, a second through hole pattern, a fourth conductive pattern, and a third through hole pattern corresponding to the display panel of FIG. 16.

In some embodiments, as shown in FIG. 32, in the same pixel group (e.g., the first pixel group 110), the first active structure 421, the second active structure 422, the third active structure 423, and the fourth active structure 424 overlap with different first conductive structures 4100, respectively. In some embodiments, the first active structure 421 in the first pixel group 110 and the third active structure 423 in the second pixel group 120 overlap with the same first conductive structure 4100, and the second active structure 422 in the first pixel group 110 and the fourth active structure 424 in the second pixel group 120 overlap with the same first conductive structure 4100.

In some embodiments, as shown in FIGS. 21 and 33, a first active structure 421 in the first pixel group 110 and a third active structure 423 in the second pixel group 120 overlap with the same connection zone 4301, and a second active structure 422 in the first pixel group 110 and a fourth active structure 424 in the second pixel group 120 overlap with the same connection zone 4301.

In some embodiments, as shown in FIG. 34, in the same pixel group (e.g., the first pixel group 110), a first connecting end 4211 of the first active structure 421, a first connecting end 4221 of the second active structure 422, a second connecting end 4232 of the third active structure 423, and a second connecting end 4242 of the fourth active structure 424 respectively correspond to one first through hole 5100, and are at least partially exposed by their respective corresponding first through hole 5100.

In some embodiments, as shown in FIGS. 19 and 20, the third conductive structure 4400 can be the first data line D1 or the second data line D2, the first connecting end 4211 of the first active structure 421 and the first connecting end 4221 of the second active structure 422 are respectively connected with the first data line D1 through their corresponding first through hole 5100. The second connecting end 4232 of the third active structure 423 and the second connecting end 4242 of the fourth active structure 424 is connected with the second data line D2 through their corresponding first through hole 5100.

In some embodiments, as shown in FIGS. 22 and 27, the second connecting end 4212 of the first active structure 421, the second connecting end 4222 of the second active structure 422, the first connecting end 4231 of the third active structure 423, and the first connecting end 4241 of the fourth active structure 424 respectively correspond to one second through hole 5200 and are at least partially exposed by their respective corresponding second aperture 5200.

In some embodiments, as shown in FIGS. 17 and 35, at least a portion of the fourth conductive structure 4500 is in the second through hole 5200, and at least a portion of the fourth conductive structure 4500 is exposed by the second through hole 5200.

In some embodiments, as shown in FIGS. 16 and 17, at least a portion of the pixel electrode 200 is in the fourth through hole 5400 and is in contact with the fourth conductive structure 4500 for connection, thus the pixel electrode 200 can be connected with the active structure 4200 through the fourth conductive structure 4500.

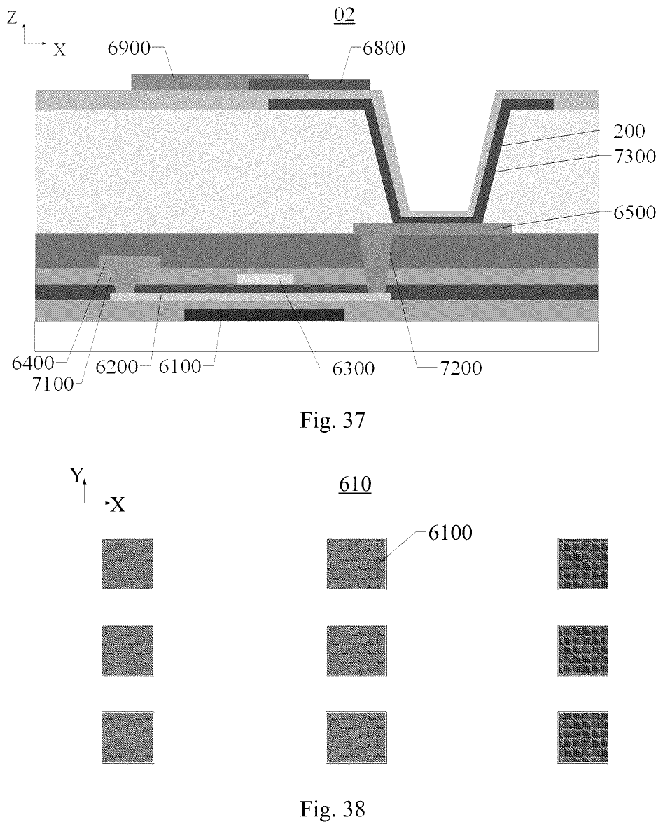

FIG. 36 is a schematic diagram of a partial structure of another display panel provided by at least one embodiment of the present disclosure. FIG. 37 is a schematic diagram of a partial cross-section corresponding to the display panel of FIG. 36.

In some embodiments, as shown in FIG. 36 and FIG. 37, the display panel 02 includes the base substrate BS, and the buffer layer BF, the gate insulation layer G1, the first interlayer dielectric layer ILD1, the second interlayer dielectric layer ILD2, the planarization layer PLN, and the passivation layer PVX arranged in turn in the third direction Z perpendicular to the base substrate BS. In some embodiments, the display panel 02 further includes the first conductive structure 6100, the active structure 6200, the second conductive structure 6300, the third conductive structure 6400, the fourth conductive structure 6500, the common electrode 6900 and the pixel electrode 200 corresponding to each sub-pixel. The third conductive structure 6400 is connected with the active structure 6200 through the first through hole 7100.

In some embodiments, as shown in FIG. 37, the stacking order and connection relationship of each film structure between the base substrate BS and the fourth conductive structure 6500 in the display panel 02 are the same as those of the display panel 01 shown in FIG. 17, and will not be repeated here.

In some embodiments, as shown in FIG. 37, the pixel electrode 200 is arranged between the planarization layer PLN and the passivation layer PVX, and at least part of the pixel electrode 200 is located in the third through hole 7300 to contact the fourth conductive structure 6500, the fourth conductive structure 6500 is connected with the active structure 6200 through the second through hole 7200, so that the connection between the pixel electrode 200 and the active structure 6200 can be realized. The common electrode 6900 is arranged on the passivation layer PVX and is in contact with the passivation layer PVX, so that the common electrode 6900 can form an electric field with the pixel electrode 200 to drive the deflection of liquid crystal molecules. In some embodiments, in order to reduce the resistance of the common electrode 6900, the display panel 02 also includes an auxiliary electrode 6800. At least part of the auxiliary electrode 6800 is arranged between the common electrode 6900 and the passivation layer PVX, and the auxiliary electrode 6800 is connected with the common electrode 6900.

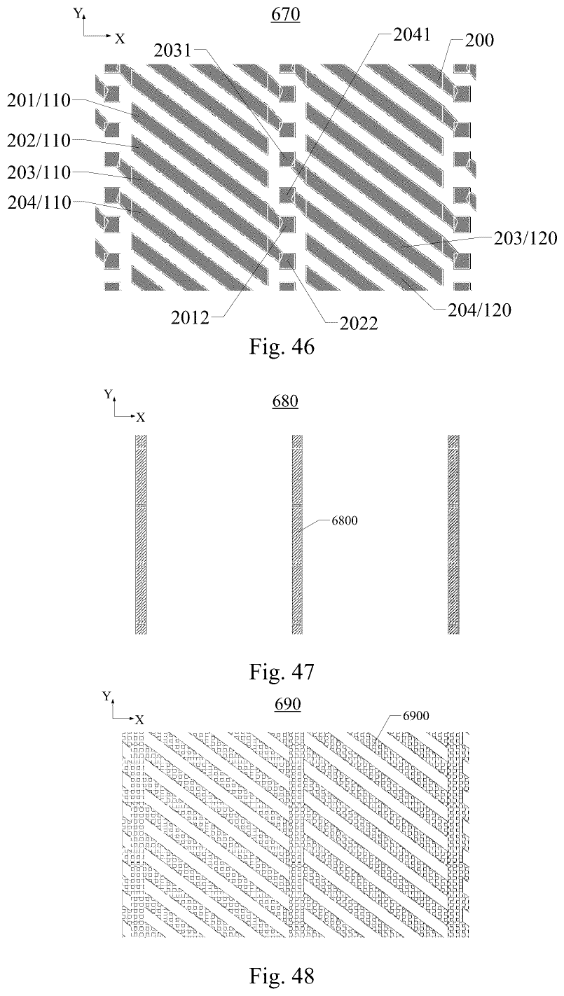

It is understood that the structure of the display panel provided in embodiments of the present disclosure is not limited to the structure shown in FIG. 36 and FIG. 37, and the structure of each film layer in the display panel can be flexibly arranged according to the needs, and the embodiments of the present disclosure are not limited thereto. The common electrode is not shown in FIG. 36 for the sake of clarity, and the structure of the common electrode can be described in FIG. 37 and FIG. 46 (see subsequent embodiments).

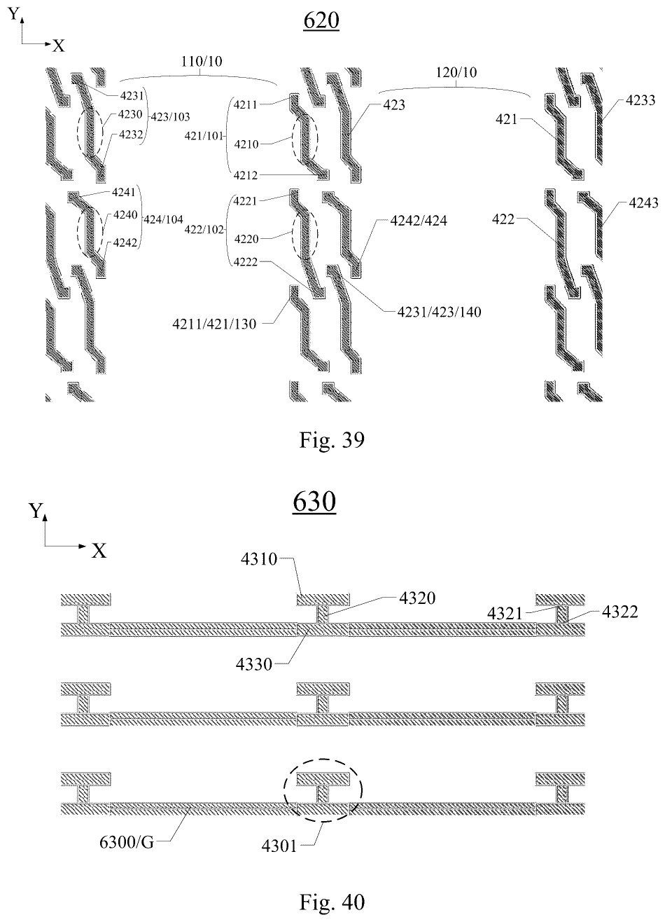

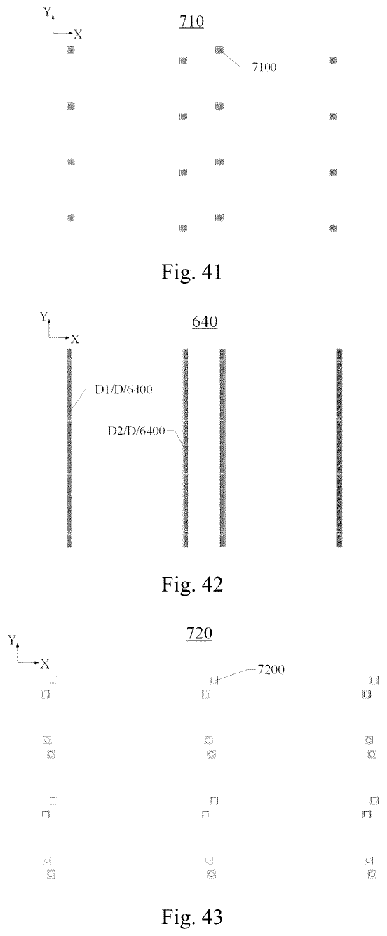

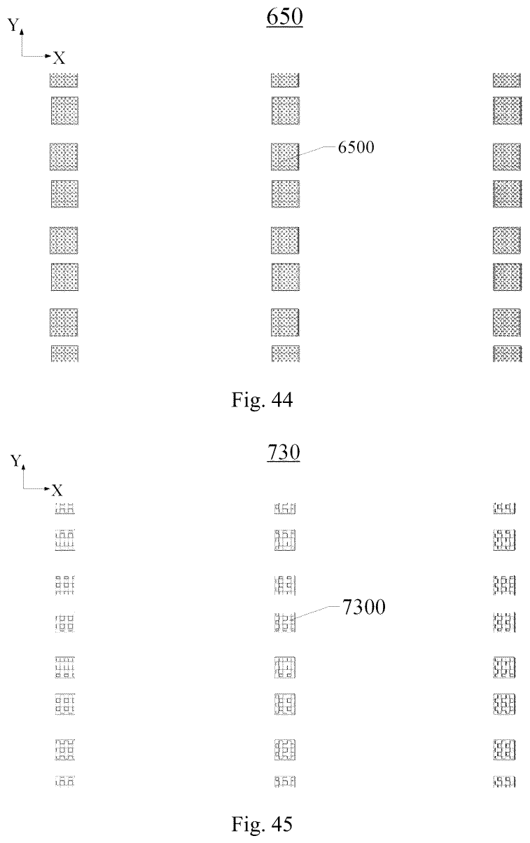

FIG. 38 is a schematic diagram of the first conductive pattern corresponding to the display panel in FIG. 36. FIG. 39 is a schematic diagram of the active pattern corresponding to the display panel in FIG. 36. FIG. 40 is a schematic diagram of the second conductive pattern corresponding to the display panel in FIG. 36. FIG. 41 is a schematic diagram of the first through hole pattern corresponding to the display panel in FIG. 36. FIG. 42 is a schematic diagram of a third conductive pattern corresponding to the display panel in FIG. 36. FIG. 43 is a schematic diagram of the second through hole pattern corresponding to the display panel in FIG. 36. FIG. 44 is a schematic diagram of the fourth conductive pattern corresponding to the display panel in FIG. 36. FIG. 45 is a schematic diagram of the third through hole pattern corresponding to the display panel of FIG. 36. FIG. 46 is a schematic diagram of the pixel electrode pattern corresponding to the display panel in FIG. 36. FIG. 47 is a schematic diagram of the auxiliary electrode pattern corresponding to the display panel in FIG. 36. FIG. 48 is a schematic diagram of the common electrode pattern corresponding to the display panel in FIG. 36.

In some embodiments, as shown in FIGS. 37 and 38, the first conductive pattern 610 includes a plurality of first conductive structures 6100, and the plurality of first conductive structures 6100 correspond one-to-one with the plurality of sub-pixels 100 (please refer to FIG. 15).

In some embodiments, as shown in FIG. 37 and FIG. 39, a gate insulation layer G1 and a first interlayer dielectric layer ILD1 are arranged on the active structure 6200. The first through hole 7100 penetrates the gate insulation layer G1 and the first interlayer dielectric layer ILD1 between the third conductive structure 6400 and the active structure 6200, thus realizing the connection between the third conductive structure 6400 and the active structure 6200. For example, the plurality of active structures 6200 in the display panel 02 include the first active structure 421, the second active structure 422, the third active structure 423, and the fourth active structure 424.

In some embodiments, as shown in FIG. 39, the display panel 02 includes a first pixel group 110 and a second pixel group 120 that are adjacent to each other in the row direction X, and a third pixel group 130 and a fourth pixel group 140 that are adjacent to each other in the row direction X, the first pixel group 110 and the third pixel group 130 are adjacent to each other in the column direction Y, and the second pixel group 120 and the fourth pixel group 140 are adjacent to each other in the column direction Y. In the row direction X, the first connecting end 4211 of the first active structure 421 in the third pixel group 130, the second connecting end 4222 of the second active structure 422 in the first pixel group 110, the first connecting end 4231 of the third active structure 423 in the fourth pixel group 140, and the second connecting end 4242 of the fourth active structure 424 in the second pixel group 120 are arranged in sequence. In the row direction X, the second connecting end 4222 of the second active structure 422 in the first pixel group 110 overlaps with the first active structure 421 in the third pixel group 130 and the third active structure 423 in the fourth pixel group 140. The first connecting end 4231 of the third active structure 423 in the fourth pixel group 140 overlaps with the second active structure 422 in the first pixel group 110 and the fourth active structure 424 in the second pixel group 120.

In some embodiments, as shown in FIG. 39, the first active structure 421 includes the first extension portion 4210, the second active structure 422 includes the second extension portion 4220, the third active structure 423 includes the third extension portion 4230, and the fourth active structure 424 includes the fourth extension portion 4240. In some embodiments, the first extension portion 4210 is located between the first connecting end 4211 of the first active structure 421 and the second connecting end 4212 of the first active structure 421; the second extension portion 4220 is located between the first connecting end 4221 of the second active structure 422 and the second connecting end 4222 of the second active structure 422; and the third extension portion 4230 is located between the first connecting end 4231 of the third active structure 423 and the second connecting end 4232 of the third active structure 423; the fourth extension portion 4240 is located between the first connecting end 4241 of the fourth active structure 424 and the second connecting end 4242 of the fourth active structure 424. In some embodiments, the first extension portion 4210, the second extension portion 4220, the third extension portion 4230, and the fourth extension portion 4240 extend in the column direction Y. For the connection relationship and position relationship of the first active structure, the second active structure, the third active structure and the fourth active structure, please refer to the relevant description of the above embodiments, and will not repeat the description here.

In some embodiments, as shown in FIG. 40, the structure and position of the second conductive structure 6300 can be adjusted accordingly according to the active structure 6200 in FIG. 39. The second conductive structure 6300 can be used as the scanning line G. The scanning line G includes a connection zone 4301; the connection zone 4301 includes a first structural portion 4310, a second structural portion 4320, and a third structural portion 4330. The first structural portion 4310 and the third structural portion 4330 extend in the row direction X, the first structural portion 4310 and the third structural portion 4330 are arranged at intervals in the column direction Y, and the second structural portion 4320 extends in the column direction Y, One end 4321 of the second structural portion 4320 is connected with the first structural portion 4310, and the other end 4322 of the second structural portion 4320 is connected with the third structural portion 4330. For example, compared with the scanning line G shown in FIG. 21, the connection zone 4301 of the scanning line G in FIG. 40 is larger has a larger size in the row direction X.

In some embodiments, as shown in FIGS. 37 and 41, the position of the first through hole 7100 can be adjusted accordingly according to the active structure 6200 in FIG. 39. For example, compared with the first through hole 5100 shown in FIG. 24, the distance between the two first through hole 7100 adjacent to each other in the row direction X in FIG. 41 is larger. For other structures and connection modes of the first through hole 7100 shown in FIG. 41, please refer to the relevant description of FIG. 24 in the above embodiment, which will not be repeated here.

In some embodiments, as shown in FIGS. 37 and 42, the third conductive structure 6400 extends along the column direction Y and can be used as data line D, such as the first data line D1 or the second data line D2. For example, compared with the third conductive structure 6400 shown in FIG. 25, the distance between the two third conductive structures 6400 adjacent to each other in the row direction X in FIG. 42 is larger. For other structures and connection modes of the third conductive structure 6400 shown in FIG. 42, please refer to the relevant description of the above embodiment, and will not repeat the description here.

In some embodiments, as shown in FIG. 37 and FIG. 43, the second interlayer dielectric layer ILD2 is arranged on the first interlayer dielectric layer ILD1, and the second through hole 7200 penetrates the second interlayer dielectric layer ILD2, the first interlayer dielectric layer ILD1 and the gate insulation layer G1 between the fourth conductive structure 6500 and the active structure 6200, thus realizing the connection the fourth conductive structure 6500 and the active structure 6200. In some embodiments, as shown in FIG. 43, the two second through holes 7200 adjacent to each other in the column direction Y can be staggered in the row direction X to better adapt to the position of the active structure 6200 in FIG. 39.

In some embodiments, as shown in FIG. 37 and FIG. 44, the second interlayer dielectric layer ILD2 is arranged on the first interlayer dielectric layer ILD1, and the second through hole 7200 penetrates the second interlayer dielectric layer ILD2, the first interlayer dielectric layer ILD1, and the gate insulation layer G1 between the fourth conductive structure 6500 and the active structure 6200, thus realizing the connection between the fourth conductive structure 6500 and the active structure 6200.

In some embodiments, as shown in FIG. 37 and FIG. 45, the third through hole 7300 is formed in the planarization layer PLN, and the planarization layer PLN is penetrated to expose at least part of the fourth conductive structure 6500.

In some embodiments, as shown in FIGS. 37 and 46, at least a portion of the pixel electrode 200 is in a third through hole 7300 to connect to a fourth conductive structure 6500, thus the pixel electrode 200 is connected with the active structure 6200 through the fourth conductive structure 6500.

In some embodiments, as shown in FIG. 46, in the column direction Y, the first end 2031 of the third pixel electrode 203 in the second pixel group 120, the first end 2041 of the fourth pixel electrode 204 in the second pixel group 120, the second end 2012 of the first pixel electrode 201 in the first pixel group 110, and the second end 2022 of the second pixel electrode 202 in the first pixel group 110 are arranged at intervals in sequence. In some embodiments, in the column direction Y, the second end 2012 of the first pixel electrode 201 in the first pixel group 110 is adjacent to the second end 2022 of the second pixel electrode 202 in the first pixel group 110, and the first end 2031 of the third pixel electrode 203 in the second pixel group 120 is adjacent to the first end 2041 of the fourth pixel electrode 204 in the second pixel group 120. In some embodiments, in the same pixel group (for example, the first pixel group 110), the main body extension direction of each pixel electrode 200 is the same, and each pixel electrode 200 does not include a local structure (for example, a connection structure, etc.) that extend in different directions from the main body, which can make the structure of pixel electrodes 200 simpler and more uniform, in order to simplify the production process. For other structural features and connection mode of pixel electrode 200, please refer to the relevant description of FIG. 18 in the above embodiment, which will not be repeated here.

In some embodiments, as shown in FIGS. 37 and 47, the auxiliary electrode pattern 680 includes a plurality of auxiliary electrodes 6800, the auxiliary electrodes 6800 extend along the column direction Y. In some embodiments, the auxiliary electrode 6800 may include a conductive material. The auxiliary electrode 4600 is arranged on the passivation layer PVX. In some embodiments, a part of the auxiliary electrode 6800 can be located in the planarization layer PLN, and the other part can be arranged on the side of the passive layer PVX facing away from the base substrate BS. In some embodiments, the auxiliary electrode 6800 can also be located in the passivation layer PVX, and the surface of the auxiliary electrode 6800 facing away from the base substrate BS is exposed outside the passivation layer PVX to facilitate the connection with the common electrode 6900. The embodiments of this disclosure do not limit the setting form of the auxiliary electrode 6800. Such setting is conducive to reducing the overall size of display panel 02 in column direction Y, so as to facilitate lightweight design.

In some embodiments, as shown in FIG. 37 and FIG. 48, the common electrode pattern 690 includes the common electrode 6900, and the common electrode 6900 can be an integrated mesh structure to ensure signal uniformity. As shown in FIG. 37, the orthographic projection of the common electrode 6900 on the base substrate BS overlaps partially with the orthographic projection of the auxiliary electrode 6800 on the base substrate BS.

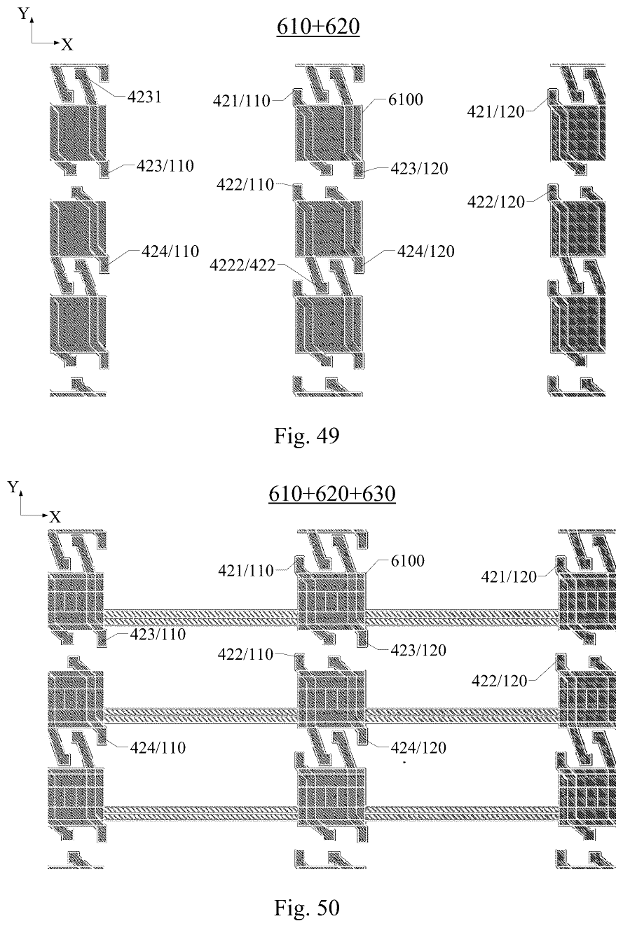

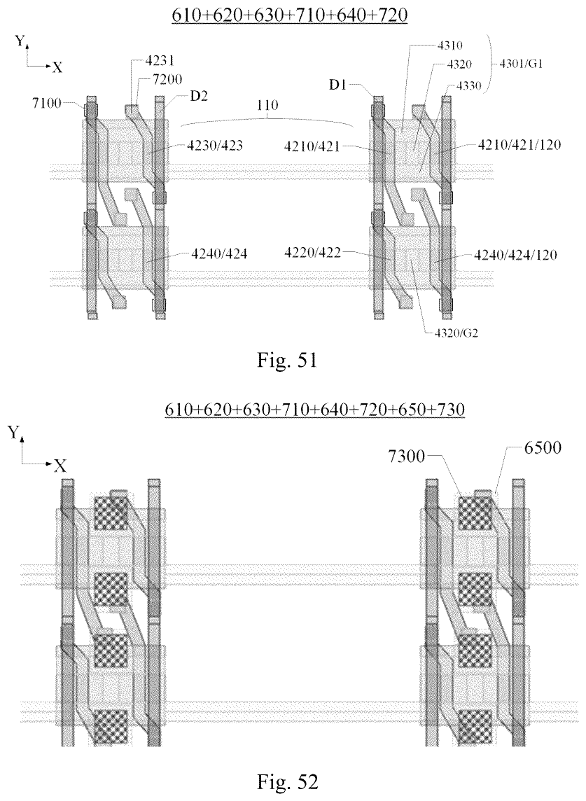

FIG. 49 is a schematic diagram of a stacking structure of the first conductive pattern and the active pattern corresponding to the display panel of FIG. 36. FIG. 50 is a schematic diagram of a stacking structure of the first conductive pattern, the active pattern, and the second conductive pattern corresponding to the display panel of FIG. 36. FIG. 51 is a schematic diagram of a stacking structure of the first conductive pattern, the active pattern, the second conductive pattern, the first through hole pattern, the third conductive pattern, and the second through hole pattern corresponding to the display panel of FIG. 36. FIG. 52 is a schematic diagram of a stacking structure of the first conductive pattern, the active pattern, the second conductive pattern, the first through hole pattern, the third conductive pattern, the second through hole pattern, the fourth conductive pattern, and the third through hole pattern corresponding to the display panel of FIG. 36.

In some embodiments, compared with the stack structure shown in FIG. 32, as shown in FIG. 49, in the column direction Y, the second connecting end 4222 of the second active structure 422 is far away from the first conductive structure 6100 overlapped with the second active structure 422, and the first connecting end 4231 of the third active structure 423 is far away from the first conductive structure 6100 overlapped with the third active structure 423. In some embodiments, as shown in FIGS. 39 and 49, the first extension portion 4210, the second extension portion 4220, the third extension portion 4230, and the fourth extension portion 4240 all overlap with their corresponding first conductive structure 6100.

In some embodiments, as shown in FIGS. 40 and 50, a first active structure 421 in the first pixel group 110 and a third active structure 423 in the second pixel group 120 overlap with the same connection zone 4301, and a second active structure 422 in the first pixel group 110 and a fourth active structure 424 in the second pixel group 120 overlap with the same connection zone 4301.

In some embodiments, as shown in FIGS. 39 and 51, in the same pixel group (for example, the first pixel group 110), the first connecting end 4211 of the first active structure 421, the first connecting end 4221 of the second active structure 422, the second connecting end 4232 of the third active structure 423, and the second connecting end 4242 of the fourth active structure 424 correspond to one first through hole 7100, respectively. In some embodiments, the first connecting end 4211 of the first active structure 421 and the first connecting end 4221 of the second active structure 422 are respectively connected with the first data line D1 through their corresponding first through hole 7100. The second connecting end 4232 of the third active structure 423 and the second connecting end 4242 of the fourth active structure 424 are respectively connected with the second data line D2 through their corresponding first through hole 7100. For example, the second connecting end 4212 of the first active structure 421, the second connecting end 4222 of the second active structure 422, the first connecting end 4231 of the third active structure 423, and the first connecting end 4241 of the fourth active structure 424 respectively correspond to one second through hole 7200, and are at least partially exposed by their corresponding second through hole 7200.

In some embodiments, as shown in FIG. 51, in the column direction Y, in the same pixel group (such as the first pixel group 110), the first extension portion 4210 of the first active structure 421 is arranged between the first structural portion 4310 and the third structural portion 4330 of the first scanning line G1 adjacent to the first extension portion 4210 of the first active structure 421; and the third extension portion 4230 of the third active structure 423 is arranged between the first structural portion 4310 and the third structural portion 4330 of the first scanning line G1 adjacent to the third extension portion 4230 of the third active structure 423. That is, the first extension portion 4210 of the first active structure 421 is arranged between the first structural portion 4310 and the third structural portion 4330 of a connection zone 4301 of the first scanning line G1, and the third extension portion 4230 of the third active structure 423 is arranged between the first structural portion 4310 and the third structural portion 4330 of another connection zone 4301 of the first scanning line G1. In some embodiments, in column direction Y, the second extension portion 4220 of the second active structure 422 is arranged between the first structural portion 4310 and the third structural portion 4330 of the second scanning line G2 adjacent to the second extension portion 4220 of the second active structure 422; and the fourth extension portion 4240 of the fourth active structure 424 is arranged between the first structural portion 4310 and the third structural portion 4330 of the second scanning line G2 adjacent to the fourth extension portion 4240 of the fourth active structure 424. That is, the second extension portion 4220 of the second active structure 422 is arranged between the first structural portion 4310 and the third structural portion 4330 of a connection zone 4301 of the second scanning line G2, and the fourth extension portion 4240 of the fourth active structure 424 is arranged between the first structural portion 4310 and the third structural portion 4330 of another connection zone 4301 of the second scanning line G2.

In some embodiments, as shown in FIG. 51, in the row direction X, the first extension portion 4210 in the first pixel group 110 and the third extension portion 4230 in the second pixel group 120 are respectively located on both sides of the second structural portion 4320 of the first scanning line G1. The second extension portion 4220 in the first pixel group 110 and the fourth extension portion 4240 in the second pixel group 120 are respectively located on both sides of the second structural portion 4320 of the second scanning line G2. In some embodiments, in the row direction X, the first extension portion 4210 in the first pixel group 110 and the third extension portion 4230 in the second pixel group 120 are arranged at intervals with the second structural portion 4320 of the first scanning line G1, the second extension portion 4220 in the first pixel group 110 and the fourth extension portion 4240 in the second pixel group 120 are arranged at intervals with the second structural portion 4320 of the second scanning line G2.

This setting can reduce the risk of signal crosstalk between the first active structure and the third active structure and the second structural portion of the first scanning line as well as the risk of signal crosstalk between the second active structure and the fourth active structure and the second structural portion of the second scanning line, thereby ensuring the reliability of signal transmission in the connection zone of the first scanning line and the connection zone of the second scanning line.

In some embodiments, as shown in FIGS. 37 and 52, at least a portion of the fourth conductive structure 6500 is in the second through hole 7200, and at least a portion of the fourth conductive structure 4500 is exposed by the second through hole 7200.

In some embodiments, as shown in FIGS. 36 and 37, at least a portion of the pixel electrode 200 is in the third through hole 7300 and is in contact with the fourth conductive structure 6500 for connection, thus the pixel electrode 200 can be connected with the active structure 6200 through the fourth conductive structure 6500.

For other structural features of the stacked structure illustrated in FIGS. 49 to 52, please refer to the relevant descriptions of the above embodiments, which will not be repeated herein.

During specific implementation, the display panel includes: an array substrate and an opposite substrate that are opposite each other, and a liquid crystal layer between the array substrate and the opposite substrate.

In some embodiments, the opposite substrate includes a light-shielding layer, and the light-shielding layer includes sub-pixel aperture zones. That is, a pattern of the light-shielding layer may be designed to match shapes of the required sub-pixel aperture zones.

In some embodiments, the array substrate includes a plurality of scanning lines extending in the row direction x and a plurality of data lines extending in the column direction y.

During specific implementation, regardless of the shapes of the sub-pixel aperture zones, an extension direction of the scanning lines may be set to be parallel to the row direction x and an extension direction of the data lines may be set to be parallel to the column direction y. That is, the extension directions of the scanning lines and the data lines are independent of the shapes of the sub-pixel aperture zones.

During specific implementation, the array substrate includes driving units one-to-one corresponding to the sub-pixels, and the plurality of scanning lines and the plurality of data lines arranged in a crossed manner define zones of the driving units. When the row direction is perpendicular to the column direction, the zones of the driving units are roughly in shapes of rectangles. The shape of the zone of each driving unit may match a shape of the sub-pixel aperture zone. For example, the zone of the driving unit and the sub-pixel aperture zone are both in shapes of rectangles, and alternatively, the zone of the driving unit may be in the shape of a rectangle while the sub-pixel aperture zone is in the shape of a parallelogram.

In some embodiments, the display apparatus further includes:
an eye-tracking system configured to determine a position of eyes of a user in real time.

During specific implementation, in a 2D display mode, a first image driving signal corresponding to each pixel island may be determined according to an image to be displayed, the corresponding first image driving signals may be loaded to all sub-pixels in the pixel island, and further a 2D image is formed. In a 3D display mode, the eye-tracking system determines coordinates of the eyes of the user, image information to be displayed is determined, according to the image information to be displayed, second image driving signals corresponding to all viewpoints are determined and applied to the sub-pixels of each pixel island, and further a three dimensional image is formed. During specific implementation, a left-eye view and a right-eye view may be determined according to the coordinates of the eyes of the user, sub-pixels corresponding to the left-eye view and sub-pixels corresponding to the right-eye view in each pixel island group may be determined, driving signals corresponding to the left-eye view are supplied to the sub-pixels corresponding to the left-eye view, and driving signals corresponding to the right-eye view are supplied to the sub-pixels corresponding to the right-eye view; and alternatively, the second image driving signals corresponding to the same viewpoint may be applied to the sub-pixels at the same positions in different pixel islands, and further a 3D image having too many viewpoints is formed.

The display apparatus provided in some embodiments of the present disclosure is any product or component with a display function, such as a mobile phone, a tablet computer, a television, a display, a notebook computer, a digital photo frame, and a navigator. Other essential components of the display apparatus should be understood by those of ordinary skill in the art, which will not be repeated herein and should not limit the present disclosure.

In conclusion, according to the display apparatus according to the embodiment of the present disclosure, both the included angle between the extension direction of the light-splitting structures and the preset horizontal direction X and the included angle between the extension direction of the light-splitting structures and the preset vertical direction Y are greater than 0, that is, the light-splitting structures are obliquely placed relative to the preset horizontal direction X and the preset vertical direction Y, such that the human eyes may see the parallax image in both the preset horizontal direction and the preset vertical direction, and further the display apparatus may achieve bidirectional 3D display and improve user experience.

Although preferred embodiments of the present disclosure have been described, those skilled in the art can still make additional changes and modifications to the embodiments once they learn the basic inventive concept. Therefore, the appended claims are intended to be interpreted as including the preferred embodiments and all changes and modifications falling within the scope of the present disclosure.

Apparently, those skilled in the art can make various modifications and variations to the embodiments of the present disclosure without departing from the spirit and scope of the embodiments of the present disclosure. In this way, if the modifications and variations of the embodiments of the present disclosure fall within the scope of the claims of the present disclosure and their equivalent technologies, the present disclosure is also intended to include the modifications and variations.

What is claimed is:

1. A display apparatus, comprising:
a display panel comprising: a plurality of sub-pixels arranged in arrays in a row direction and a column direction, the plurality of sub-pixels are divided into a plurality of pixel islands; each of the pixel islands comprises n sub-pixels arranged at intervals in the row direction, wherein n is an integer greater than 1; and the display panel comprises a preset horizontal direction and a preset vertical direction perpendicular to the preset horizontal direction; and
a light-splitting assembly at a display side of the display panel, wherein the light-splitting assembly comprises a plurality of light-splitting repeating units extending in a first direction and continuously arranged in the preset horizontal direction; each of the light-splitting repeating units comprises M light-splitting structures extending in the first direction; in the row direction, a width of the M light-splitting structures is equal to a width of K pixel islands, wherein M and K are positive integers; and both an included angle between the first direction and the preset horizontal direction and an included angle between the first direction and the preset vertical direction are greater than 0.

2. The display apparatus according to claim 1, wherein the plurality of sub-pixels are divided into a plurality of pixel groups, the plurality of pixel groups are arranged in arrays in the row direction and the column direction, each of the pixel groups comprises: a first sub-pixel, a second sub-pixel, a third sub-pixel, and a fourth sub-pixel arrayed sequentially in the column direction;
the display panel further comprises: an array substrate;
the array substrate comprises:
a plurality of data lines, arranged at intervals in the row direction, and each of the data lines extending in the column direction;
a plurality of scanning lines, arranged at intervals in the column direction, and each of the scanning lines extending in the row direction;
wherein the plurality of scanning lines comprise a first scanning line and a second scanning line adjacent to each other in the column direction, the first scanning line is configured to apply a first scanning signal to the first sub-pixel and the third sub-pixel, the second scanning line is configured to apply a second scanning signal to the second sub-pixel and the fourth sub-pixel; and
the plurality of data lines comprise a first data line and a second data line, the first data line is configured to apply a first data signal to the third sub-pixel and the fourth sub-pixel, the second data line is configured to apply a second data signal to the first sub-pixel and the second sub-pixel.

3. The display apparatus according to claim 2, wherein each of the sub-pixels comprises a pixel electrode, the first sub-pixel comprises a first pixel electrode, the second sub-pixel comprises a second pixel electrode, the third sub-pixel comprises a third pixel electrode, the fourth sub-pixel comprises a fourth pixel electrode; and the first pixel electrode, the second pixel electrode, the third pixel electrode, and the fourth pixel electrodes are sequentially arranged in the column direction;
angles between main body extension directions of the first pixel electrode, the second pixel electrode, the third pixel electrode, and the fourth pixel electrode and the row direction are greater than 0; and
angles between the main body extension directions of the first pixel electrode, the second pixel electrode, the third pixel electrode, and the fourth pixel electrode and the column direction are greater than 0.

4. The display apparatus according to claim 3, wherein the first pixel electrode, the second pixel electrode, the third pixel electrode, and the fourth pixel electrode have a same main body extension direction; and the main body extension direction is the same as the first direction.

5. The display apparatus according to claim 3, wherein each of the pixel electrodes comprises a first end and a second end arranged opposite with each other;
at least a portion of a second end of the first pixel electrode is arranged on a side of the first scanning line proximate to the second scanning line; at least a portion of a first end of the third pixel electrode is arranged on a side of the first scanning line far away from the second scanning line; at least a portion of a second end of the second pixel electrode is arranged on a side of the second scanning line far away from the first scanning line; and at least a portion of a first end of the fourth pixel electrode is arranged on a side of the second scanning line proximate to the first scanning line;
in a same pixel group, the first pixel electrode and the third pixel electrode are overlapped with the first scanning line, the second pixel electrode and the fourth pixel electrode are overlapped with the second scanning line, at least a portion of a first end of the second pixel electrode is arranged on the side of the first scanning line far away from the second scanning line, and at least a portion of a second end of the fourth pixel electrode is arranged on the side of the second scanning line far away from the first scanning line.

6. The display apparatus according to claim 5, wherein each of the sub-pixels comprises an active structure, and the active structure comprises a first connecting end and a second connecting end arranged opposite with each other; wherein the first sub-pixel comprises a first active structure, the second sub-pixel comprises a second active structure, the third sub-pixel comprises a third active structure, and the fourth sub-pixel comprises a fourth active structure;
a first connecting end of the first active structure is connected with the second data line, a second connecting end of the first active structure is connected with the second end of the first pixel electrode;
a first connecting end the second active structure is connected with the second data line, a second connecting end of the second active structure is connected with the second end of the second pixel electrode;
a first connecting end of the third active structure is connected with the first end of the third pixel electrode, a second connecting end of the third active structure is connected with the first data line;
a first connecting end of the fourth active structure is connected with the first end of the fourth pixel electrode, a second connecting end of the fourth active structure is connected with the first data line.

7. The display apparatus according to claim 6, wherein, in a same pixel group, the first active structure and the third active structure are arranged facing with each other in the row direction, the second active structure and the fourth active structure are arranged facing with each other in the row direction, both the second active structure and the fourth active structure are arranged on a same side of the first active structure in the column direction;
in the column direction, the first connecting end and the second connecting end of the first active structure of the first sub-pixel are arranged different sides of the first scanning line respectively; the first connecting end and the second connecting end of the second active structure of the second sub-pixel are arranged different sides of the second scanning line respectively; the first connecting end and the second connecting end of the third active structure of the third sub-pixel are arranged different sides of the first scanning line respectively; a first connecting end and the second connecting end of the fourth active structure of the fourth sub-pixel are arranged different sides of the second scanning line respectively.

8. The display apparatus according to claim 6, wherein the plurality of data lines comprise a plurality of first data lines and a plurality of second data lines, the plurality of first data lines and the plurality of second data lines are alternately arranged in the row direction;
the plurality of scanning lines comprise a plurality of first scanning lines and a plurality of second scanning lines, the plurality of first scanning lines and the plurality of second scanning lines are alternately arranged in the column direction;
the second connecting end of the first active structure and the second connecting end of the second active structure are arranged between the second data line connected and the first data line adjacent to the second data line connected; and the first connecting end of the third active structure and the first connecting end of the fourth active structure are arranged between the first data line connected and the second data line adjacent to the first data line connected.

9. The display apparatus according to claim 6, wherein, in the same pixel group, neither the first active structure nor the second active structure extends beyond an edge, proximate to the first data line, of the second data line connected; and neither the third active structure nor the fourth active structure extends beyond an edge, proximate to the second data line, of the first data line connected.

10. The display apparatus according to claim 6, wherein the plurality of pixel groups comprise a first pixel group and a second pixel group adjacent to each other in the row direction;
in the row direction, a first active structure in the first pixel group and a third active structure in the second pixel group are arranged at intervals and in the same row, and a second active structure in the first pixel group and a fourth active structure in the second pixel group are arranged at intervals and in the same row;
in the column direction, the first active structure in the first pixel group and the second active structure in the first pixel group are arranged at intervals and in the same column, and the third active structure in the second pixel group and the fourth active structure in the second pixel group are arranged at intervals and in the same column.

11. The display apparatus according to claim 10, wherein, in the column direction, a first end of a third pixel electrode in the second pixel group, a second end of a first pixel electrode in the first pixel group, a first end of a fourth pixel electrode in the second pixel group, and a second end of a second pixel electrode in the first pixel group are arranged at intervals in sequence.

12. The display apparatus according to claim 11, wherein the first pixel electrode comprises a first main body portion and a first connecting portion, the first main body portion is connected with the first connecting portion, one end of the first connecting portion far away from the first main body portion serves as the second end of the first pixel electrode, the first connecting portion of the first pixel electrode extends towards a direction far away from the second pixel electrode adjacent to the first pixel electrode;
the fourth pixel electrode comprises a second main body portion and a second connecting portion, the second main body portion is connected with the second connecting portion, one end of the second connecting portion far away from the second main body portion serves as the first end of the fourth pixel electrode, the second connecting portion of the fourth pixel electrode extends towards a direction far away from the third pixel electrode adjacent to the first pixel electrode.

13. The display apparatus according to claim 12, wherein an angle between an extension direction of the first connecting portion and an extension direction of the first main body portion is substantially same as an angle between an extension direction of the second connecting portion and an extension direction of the second main body portion.

14. The display apparatus according to claim 11, wherein the scanning line comprises a connection zone, the connection zone comprises a first structural portion, a second structural portion, and a third structural portion; wherein the first structural portion and the third structural portion both extend in the row direction, the first structural portion and the third structural portion are arranged at intervals in the column direction; the second structural portion extends in the column direction, one end of the second structural portion is connected with the first structural portion, and the other end of the second structural portion is connected with the third structural portion;
the first active structure comprises a first bending portion, the second active structure comprises a second bending portion, the third active structure comprises a third bending portion, the fourth active structure comprises a fourth bending portion; wherein the first bending portion and the third bending portion are arranged between the first structural portion and the third structural portion of the first scanning line adjacent to the first bending portion and the third bending portion; the second bending portion and the fourth bending portion are arranged between the first structural portion and the third structural portion of the second scanning line adjacent to the second bending portion and the fourth bending portion;
a first bending portion of the first pixel group and a third bending portion of the second pixel group are arranged on different sides of the second structural portion of the first scanning line in the row direction; the first bending portion of the first pixel group and the third bending portion of the second pixel group are concaved in a direction far away from the second structural portion of the first scanning line, respectively; and a second bending portion of the first pixel group and a fourth bending portion of the second pixel group are arranged on different sides of the second structural portion of the second scanning line in the row direction; and the second bending portion of the first pixel group and the fourth bending portion of the second pixel group are concaved in a direction far away from the second structural portion of the second scanning line, respectively.

15. The display apparatus according to claim 14, wherein a portion of the first bending portion and a portion of the second bending portion are overlapped with the second data line, and a portion of the third bending portion and a portion of the fourth bending portion are overlapped with the first data line.

16. The display apparatus according to claim 10, wherein, in the column direction, a first end of a third pixel electrode in the second pixel group, a first end of a fourth pixel electrode in the second pixel group, a second end of a first pixel electrode in the first pixel group, and a second end of a second pixel electrode in the first pixel group are arranged at intervals in sequence.

17. The display apparatus according to claim 16, wherein the scanning line comprises a connection zone, the connection zone comprises a first structural portion, a second structural portion, and a third structural portion; wherein the first structural portion and the third structural portion both extend in the row direction, the first structural portion and the third structural portion are arranged at intervals in the column direction; the second structural portion extends in the column direction, one end of the second structural portion is connected with the first structural portion, and the other end of the second structural portion is connected with the third structural portion;
the first active structure comprises a first extension, the second active structure comprises a second extension, the third active structure comprises a third extension, the fourth active structure comprises a fourth extension; wherein, in the column direction, the first extension and the third extension are arranged between the first structural portion and the third structural portion of the first scanning line adjacent to the first extension and the third extension, and the second extension and the fourth extension are arranged between the first structural portion and the third structural portion of the second scanning line adjacent to the second extension and the fourth extension;
a first extension of the first pixel group and a third extension of the second pixel group are arranged different sides of the second structural portion of the first scanning line in the row direction, and the first extension of the first pixel group and the third extension of the second pixel group extend in the column direction; and a second extension of the first pixel group and a fourth extension of the second pixel group are arranged different sides of the second structural portion of the second scanning line in the row direction, and the second extension of the first pixel group and the fourth extension of the second pixel group extend in the column direction.

18. The display apparatus according to claim 2, wherein, in the same pixel group, the first pixel electrode is in a mirror image symmetric structure with the fourth pixel electrode, and the second pixel electrode is in a mirror image symmetric structure with the third pixel electrode.

19. The display apparatus according to claim 2, wherein the display panel further comprises:
an opposite substrate arranged opposite the array substrate and comprising a light-shielding layer, wherein the light-shielding layer comprises a plurality of sub-pixel aperture zones, the plurality of sub-pixel aperture zones being arranged in one-to-one correspondence with the plurality of sub-pixels.

20. The display apparatus according to claim 1, further comprising:
a spacer dielectric layer between the light-splitting assembly and the display panel.
